(19) United States
(12) Patent Application Publication
(10) Pub. No.: US 2025/0120089 A1
(43) Pub. Date: Apr. 10, 2025

(54) NONVOLATILE MEMORY DEVICE AND MEMORY SYSTEM INCLUDING THE SAME

(71) Applicant: Samsung Electronics Co., Ltd., Suwon-si (KR)

(72) Inventors: Sehoon Lee, Suwon-si (KR); Minyong Lee, Suwon-si (KR); Junhyoung Kim, Suwon-si (KR); Jiyoung Kim, Suwon-si (KR); Sukkang Sung, Suwon-si (KR)

(21) Appl. No.: 18/830,677

(22) Filed: Sep. 11, 2024

(30) Foreign Application Priority Data
Oct. 6, 2023 (KR) 10-2023-0133771

(51) Int. Cl. H10B 43/40; G11C 16/04; H01L 23/00; H01L 25/065; H10B 41/10; H10B 41/27; H10B 41/35; H10B 41/41; H10B 43/10; H10B 43/27; H10B 43/35; H10B 80/00

(52) U.S. Cl. CPC H10B 43/40; G11C 16/0483; H01L 24/08; H01L 25/0657; H10B 41/10; H10B 41/27; H10B 41/35; H10B 41/41; H10B 43/10; H10B 43/27; H10B 43/35; H10B 80/00; H01L 2224/08146; H01L 2225/06506

(57) ABSTRACT

A nonvolatile memory device includes a peripheral circuit structure including a peripheral circuit, and a lower insulating structure on the peripheral circuit, a cell array structure having a cell area and a peripheral connection area and including an upper insulating structure in contact with the lower insulating structure, a cell stack in the cell area on the upper insulating structure, a common source line layer on the cell stack and having a common source opening, a plurality of cell channel structures extending in a vertical direction in the cell stack and into the common source line layer, and a support structure extending in the vertical direction in the cell stack and into the common source opening, and a pad pattern extending from the peripheral connection area to the cell area on the cell array structure and overlapping the support structure in the vertical direction.

### CROSS-REFERENCE TO RELATED APPLICATION(S)

This application is based on and claims priority under 35 U.S.C. § 119 to Korean Patent Application No. 10-2023-0133771, filed on Oct. 6, 2023, in the Korean Intellectual Property Office, the disclosure of which is incorporated by reference herein in its entirety.

### BACKGROUND

The inventive concept relates generally to a nonvolatile memory device, a method of manufacturing the same, and a memory system including the same. More particularly, the inventive concept relates to a three-dimensional nonvolatile memory device and a memory system including the same.

Consumers demand nonvolatile memory devices with high performance, small size, and low price. Therefore, in order to implement nonvolatile memory devices with a high degree of integration, three-dimensional nonvolatile memory devices including a plurality of memory cells arranged in a vertical direction have been proposed.

### SUMMARY

The inventive concept provides a nonvolatile memory device with structural reliability and a memory system including the same.

According to an aspect of the inventive concept, there is provided a nonvolatile memory device including a peripheral circuit structure including a peripheral circuit, a lower insulating structure covering the peripheral circuit, and a plurality of lower bonding pads on an upper surface of the lower insulating structure and electrically connected to the peripheral circuit, a cell array structure having a cell area and a peripheral connection area and including an upper insulating structure in contact with the lower insulating structure, an upper bonding pad on a lower surface of the upper insulating structure and bonded to the plurality of lower bonding pads, a cell stack arranged in the cell area on the upper insulating structure, a common source line layer on the cell stack and having a common source opening, a plurality of cell channel structures penetrating through (i.e., extending at least partially into) the cell stack and extending into the common source line layer, and a support structure penetrating through the cell stack and extending into the common source opening, and a pad pattern extending from the peripheral connection area to the cell area on the cell array structure and overlapping the support structure in a vertical direction.

According to another aspect of the inventive concept, there is provided a nonvolatile memory device including a peripheral circuit structure including a peripheral circuit, a lower insulating structure covering (i.e., on or over) the peripheral circuit, and a plurality of lower bonding pads on an upper surface of the lower insulating structure and electrically connected to the peripheral circuit, a cell array structure having a cell area and a peripheral connection area and including an upper insulating structure in contact with the lower insulating structure, an upper bonding pad on a lower surface of the upper insulating structure and bonded to the plurality of lower bonding pads, a cell stack arranged in the cell area on the upper insulating structure, a common source line layer arranged in the cell area on the cell stack and having a common source opening, a filling insulating layer covering the cell stack on the upper insulating structure, a base insulating layer filling the common source opening and covering the common source line layer and the filling insulating layer, a plurality of cell channel structures penetrating through the cell stack and extending into the common source line layer, a support structure penetrating through the cell stack, extending into the base insulating layer filling the common source opening, and not electrically connected to the plurality of upper bonding pads, and a through-contact plug penetrating through the filling insulating layer in the peripheral connection area, extending into the base insulating layer, and connected to one of the plurality of upper bonding pads, a pad pattern extending from the peripheral connection area to the cell area on the cell array structure, overlapping the support structure and the through-contact plug in a vertical direction, and electrically connected to the through-contact plug, and a pad connection via and a pad support via penetrating through the base insulating layer and connecting between the through-contact plug and the pad pattern and between the support structure and the pad pattern, the pad connection via and the pad support via including a same material.

According to another aspect of the inventive concept, there is provided a memory system including a nonvolatile memory device including a peripheral circuit structure including a peripheral circuit, a lower insulating structure covering the peripheral circuit, and a plurality of lower bonding pads on an upper surface of the lower insulating structure and electrically connected to the peripheral circuit, a cell array structure bonded to the peripheral circuit structure and having a cell area and a peripheral connection area, and a pad pattern extending from the peripheral connection area to the cell area on the cell array structure, and a memory controller electrically connected to the nonvolatile memory device through a bonding wire connected to the pad pattern and configured to control the nonvolatile memory device, wherein the cell array structure includes an upper insulating structure in contact with the lower insulating structure, an upper bonding pad on a lower surface of the upper insulating structure and bonded to the plurality of lower bonding pads, a cell stack arranged in the cell area on the upper insulating structure, a common source line layer arranged in the cell area on the cell stack and having a common source opening, a filling insulating layer covering the cell stack on the upper insulating structure, a base insulating layer filling the common source opening and covering the common source line layer and the filling insulating layer, a plurality of cell channel structures penetrating through the cell stack and extending into the common source line layer, a support structure penetrating through the cell stack, extending into the base insulating layer filling the common source opening, and not electrically connected to the plurality of upper bonding pads, a through-contact plug penetrating through the filling insulating layer in the peripheral connection area, extending into the base insulating layer, and electrically connecting the pad pattern to one of the plurality of upper bonding pads, and a pad connection via and a pad support via each penetrating through the base insulating layer and connecting between the through-contact plug and the pad pattern and between the support structure and the pad pattern.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a schematic block diagram of an example nonvolatile memory device according to one or more embodiments;

FIG. 2 is a schematic perspective view of an example nonvolatile memory device according to one or more embodiments;

FIG. 3 is an equivalent circuit diagram of a memory cell array of a nonvolatile memory device according to one or more embodiments;

FIGS. 4A and 4B are schematic layout (i.e., plan view) diagrams of an example nonvolatile memory device according to one or more embodiments;

FIGS. 5A to 5C are schematic plan views of nonvolatile memory devices according to embodiments;

FIGS. 6A to 6D are schematic cross-sectional views of example nonvolatile memory devices according to embodiments;

FIGS. 7A and 7B are schematic cross-sectional views of example nonvolatile memory devices according to embodiments;

FIGS. 8A and 8B are schematic layout diagrams of nonvolatile memory devices according to embodiments;

FIGS. 9A to 9C are schematic cross-sectional views of nonvolatile memory devices according to embodiments;

FIGS. 10A and 10B are schematic cross-sectional views of nonvolatile memory devices according to embodiments;

FIG. 11 is a schematic cross-sectional view of an example nonvolatile memory device according to one or more embodiments;

FIGS. 12A to 12C are schematic cross-sectional views of example nonvolatile memory devices according to embodiments;

FIG. 13 is a diagram schematically illustrating an example memory system including a nonvolatile memory device, according to one or more embodiments;

FIG. 14 is a perspective view schematically illustrating an example memory system including a nonvolatile memory device, according to one or more embodiments; and

FIG. 15 is a cross-sectional view schematically illustrating an example semiconductor package according to one or more embodiments.

### DETAILED DESCRIPTION

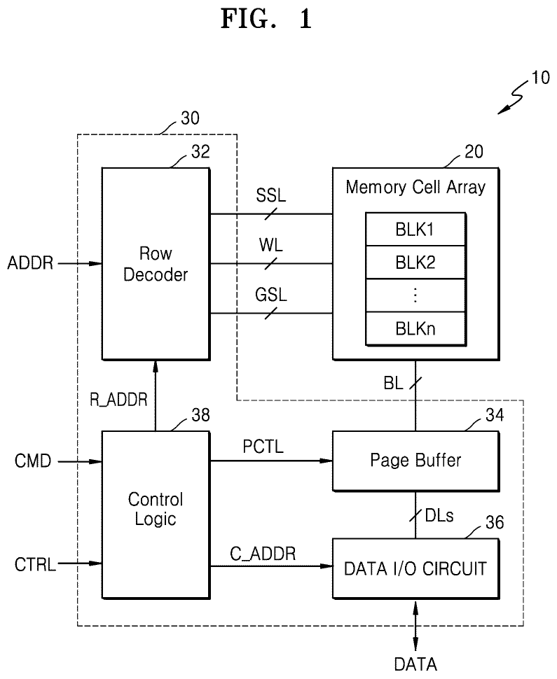

FIG. 1 is a schematic block diagram depicting at least a portion of an example nonvolatile memory device 10, according to one or more embodiments.

Referring to FIG. 1, the nonvolatile memory device 10 may include a memory cell array 20 and a peripheral circuit 30. The memory cell array 20 may include a plurality of memory cell blocks BLK1, BLK2, . . . , BLKn, where n is an integer greater than one. Each of the memory cell blocks BLK1, BLK2, . . . , BLKn may include a plurality of memory cells. The memory cell blocks BLK1, BLK2, . . . , BLKn may be connected to the peripheral circuit 30 through one or more corresponding bit lines BL, one or more corresponding word lines WL, one or more corresponding string select lines SSL, and one or more ground select lines GSL.

The peripheral circuit 30 may include a row decoder 32, a page buffer 34, a data input/output (I/O) circuit 36, and a control logic 38. In some embodiments, the peripheral circuit 30 may further include an I/O interface, a column logic, a voltage generator, a pre-decoder, a temperature sensor, a command decoder, an address decoder, an amplification circuit, and the like (not explicitly shown).

The memory cell array 20 may be connected to the page buffer 34 through the bit line BL, and may be connected to the row decoder 32 through the word line WL, the string select line SSL, and the ground select line GSL. In the memory cell array 20, each of the memory cells included in the memory cell blocks BLK1, BLK2, . . . , BLKn may be a flash memory cell. The memory cell array 20 may include a three-dimensional memory cell array. The three-dimensional memory cell array may include a plurality of NAND strings extending in a vertical direction. Each of the NAND strings may include a plurality of memory cells connected to a plurality of word lines WL stacked vertically on a substrate.

The peripheral circuit 30 may receive an external address ADDR, a command signal CMD, and a control signal CTRL from the outside of the nonvolatile memory device 10, and may transmit and receive data DATA to and from a device present in the outside of the nonvolatile memory device 10.

The row decoder 32 may select at least one of the memory cell blocks BLK1, BLK2, . . . , BLKn in response to the external address ADDR, and may select the word line WL, the string select line SSL, and the ground select line GSL of the selected memory cell block. The row decoder 32 may transmit a voltage for performing a memory operation to the word line WL of the selected memory cell block.

The page buffer 34 may be connected to the memory cell array 20 through the bit line BL. The page buffer 34 may operate as a write driver during a program operation and may apply a voltage to the bit line BL according to the data DATA to be stored in the memory cell array 20. The page buffer 34 may operate as a sense amplifier during a read operation and may detect the data DATA stored in the memory cell array 20. The page buffer 34 may operate in response to a control signal PCTL provided from the control logic 38.

The data I/O circuit 36 may be connected to the page buffer 34 through data lines DLs. The data I/O circuit 36 may receive the data DATA from a memory controller (not shown) during a program operation and may provide program data DATA to the page buffer 34 based on a column address C_ADDR provided from the control logic 38. The data I/O circuit 36 may provide, to the memory controller, read data DATA stored in the page buffer 34 based on the column address C_ADDR provided from the control logic 38 during a read operation.

The data I/O circuit 36 may transmit an input address or command to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals used in the nonvolatile memory device 10 in response to the control signal CTRL. For example, the control logic 38 may control voltage levels to be provided to the word line WL and the bit line BL during a memory operation, such as a program operation or an erase operation.

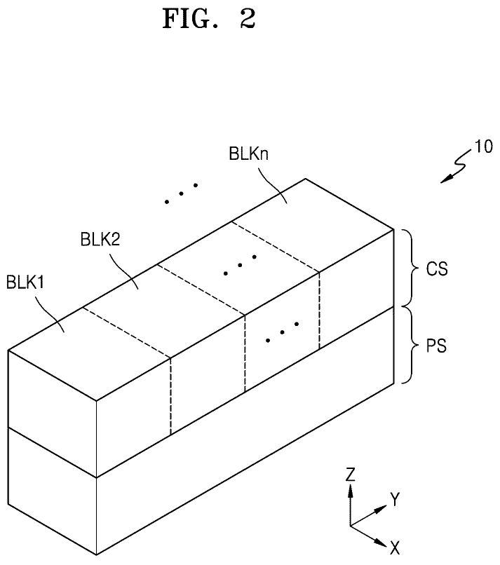

FIG. 2 is a schematic perspective view of an example nonvolatile memory device 10 according to one or more embodiments.

Referring to FIG. 2, the nonvolatile memory device 10 may include a cell array structure CS and a peripheral circuit structure PS, which overlap each other in a vertical direction (a Z direction). The term “overlap” (or “overlapping,” or like terms), as may be used herein, is intended to broadly refer to a first element that intersects with at least a portion of a second element in the vertical direction (i.e., the Z direction), but does not require that the first and second elements be completely aligned with one another in a horizontal plane (i.e., in the X direction and/or the Y direction). The cell array structure CS may include the memory cell array 20 described with reference to FIG. 1. The peripheral circuit structure PS may include the peripheral circuit 30 described with reference to FIG. 1.

The cell array structure CS may include a plurality of memory cell blocks BLK1, BLK2, . . . , BLKn. Each of the memory cell blocks BLK1, BLK2, . . . , BLKn may include memory cells arranged three-dimensionally (e.g., in a stacked configuration).

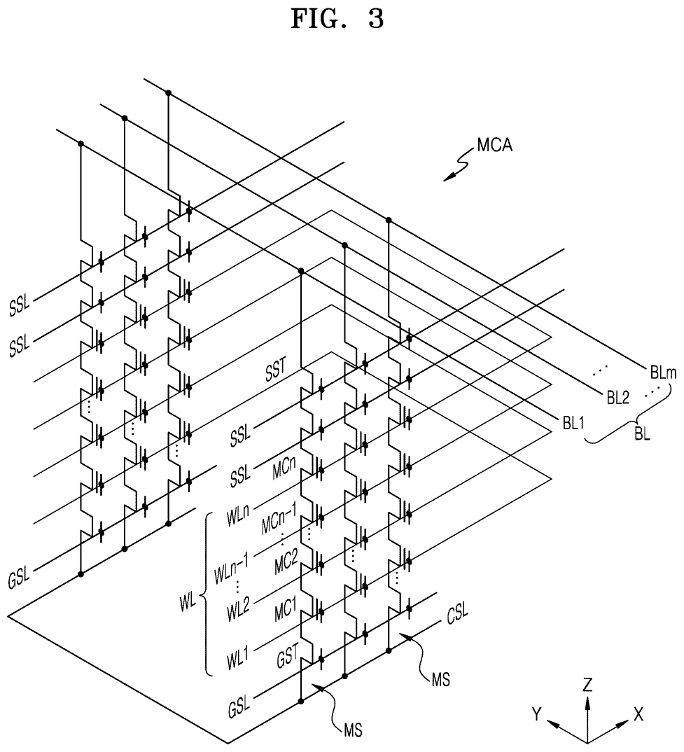

FIG. 3 is an equivalent circuit diagram of at least a portion of an example memory cell array MCA of a nonvolatile memory device, according to one or more embodiments.

Referring to FIG. 3, the memory cell array MCA may include a plurality of memory cell strings MS. The memory cell array MCA may include at least a portion of the memory cell array 20 described with reference to FIG. 1. In some embodiments, the memory cell array MCA may include at least a portion of one of the memory cell blocks BLK1, BLK2, . . . , BLKn included in the memory cell array 20 described with reference to FIG. 1.

Each of the memory cell strings MS may extend in the vertical direction (the Z direction). The memory cell array MCA may include a plurality of word lines WL (WL1, WL2, . . . , WLn−1, WLn, where n is an integer greater than one), a plurality of bit lines BL (BL1, BL2, . . . , BLm, where m is an integer greater than one that may or may not be equal to n), at least one string select line SSL, at least one ground select line GSL, and a common source line CSL. Each of the word lines WL (WL1, WL2, . . . , WLn−1, WLn) may extend in a first horizontal direction (e.g., an X direction), and each of the bit lines BL (BL1, BL2, . . . , BLm) may extend in a second horizontal direction (e.g., a Y direction) perpendicular to the first horizontal direction (the X direction). The at least one string select line SSL and the at least one ground select line GSL may each extend in the same direction as the word lines WL (WL1, WL2, . . . , WLn−1, WLn), for example, in the first horizontal direction (the X direction). The memory cell strings MS may be formed between the bit lines BL (BL1, BL2, . . . , BLm) and the common source line CSL. Although FIG. 3 illustrates a case where each of the memory cell strings MS includes two string select lines SSL, the technical idea of the inventive concept is not limited thereto. For example, each of the memory cell strings MS may include one string select line SSL.

Each of the memory cell strings MS may include a string select transistor SST, a ground select transistor GST, and a plurality of memory cell transistors MC1, MC2, . . . , MCn−1, and MCn. A drain region of the string select transistor SST may be connected to the bit lines BL (BL1, BL2, . . . , BLm), and a source region of the ground select transistor GST may be connected to the common source line CSL. The common source line CSL may be a region in which source regions of the ground select transistors GST are commonly connected.

The string select transistor SST may be connected to the string select line SSL and the ground select transistor GST may be connected to the ground select line GSL. The memory cell transistors MC1, MC2, . . . , MCn−1, and MCn may be respectively connected to the word lines WL (WL1, WL2, . . . , WLn−1, WLn).

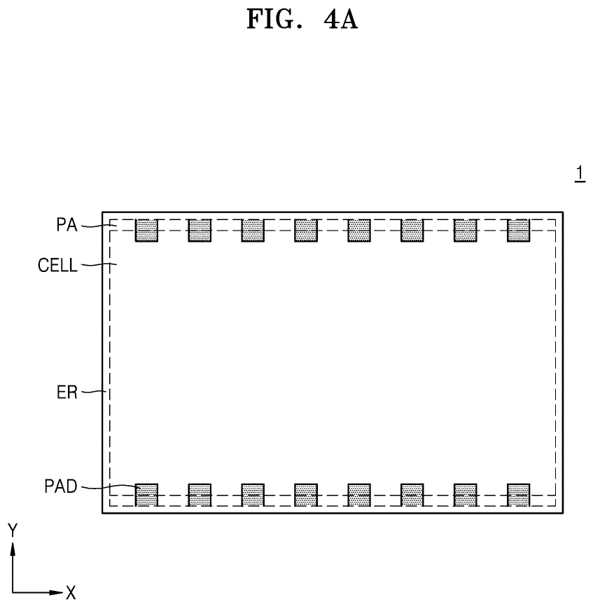

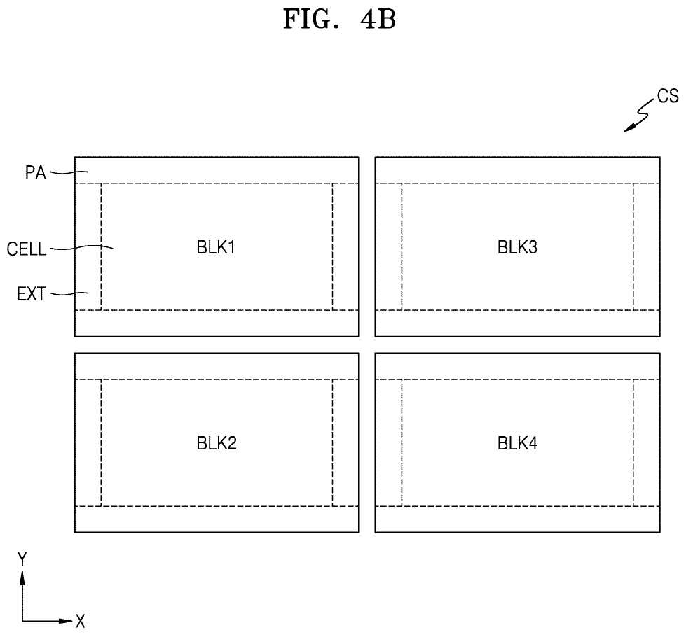

FIGS. 4A and 4B are schematic layout diagrams of a nonvolatile memory device 1, according to one or more embodiments.

Referring to FIG. 4A, the nonvolatile memory device 1 may include a cell area CELL and an edge area ER surrounding the cell area CELL in a plan view (e.g., a periphery of the memory device 1). The term “surrounding” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. A peripheral connection area PA may be between the cell area CELL and the edge area ER. In some embodiments, the peripheral connection area PA may be between the cell area CELL and the edge area ER in the second horizontal direction (Y direction) and extend in the first horizontal direction (X direction). In some embodiments, the peripheral connection area PA may be not between the cell area CELL and the edge area ER in the second horizontal direction (the Y direction).

The nonvolatile memory device 1 may include a plurality of pad patterns PAD. In some embodiments, the pad patterns PAD may be arranged adjacent to both sides of the edge area ER that are opposite to each other in the second horizontal direction (the Y direction). The pad patterns PAD may be arranged to form a row along the peripheral connection area PA. In some embodiments, the pad patterns PAD may be arranged to form a row in the first horizontal direction (the X direction), although embodiments are not limited thereto. Each of the pad patterns PAD may be located across the peripheral connection area PA and the cell area CELL. For example, a portion of each of the pad patterns PAD may be located in the peripheral connection area PA and another portion thereof may be located in the cell area CELL.

Referring to FIGS. 4A and 4B together, the nonvolatile memory device 1 may include a cell array structure CS. The nonvolatile memory device 1 may be the nonvolatile memory device 10 illustrated in FIG. 1 and the cell array structure CS may be the cell array structure CS illustrated in FIG. 2.

The cell array structure CS may include a plurality of memory cell blocks BLK1, BLK2, BLK3, and BLK4. The memory cell blocks BLK1, BLK2, BLK3, and BLK4 may be arranged to form rows and columns in the first horizontal direction (the X direction) and the second horizontal direction (the Y direction). The first horizontal direction (the X direction) may be an extension direction of each of the word lines WL (WL1, WL2, . . . , WLn−1, WLn) illustrated in FIG. 3 and the second horizontal direction (the Y direction) may be an extension direction of each of the bit lines BL (BL1, BL2, . . . , BLm) illustrated in FIG. 3. Each of the memory cell blocks BLK1, BLK2, BLK3, and BLK4 may include a plurality of memory cells.

Each of the memory cell blocks BLK1, BLK2, BLK3, and BLK4 may include a cell area CELL and a cell connection area EXT. In some embodiments, each of the memory cell blocks BLK1, BLK2, BLK3, and BLK4 may include one cell area CELL and a pair of cell connection areas EXT arranged on both (e.g., opposing) sides of the one cell area CELL. The pair of cell connection areas EXT may extend in the second horizontal direction (the Y direction) on both sides of the one cell area CELL in the first horizontal direction (the X direction). In other embodiments, each of the memory cell blocks BLK1, BLK2, BLK3, and BLK4 may include one cell area CELL and one cell connection area EXT arranged on one side of the one cell area CELL. In other embodiments, each of the memory cell blocks BLK1, BLK2, BLK3, and BLK4 may include one cell area CELL and two pairs of cell connection areas EXT arranged on both (opposing) sides of the one cell area CELL in the first horizontal direction (the X direction) and on both sides of the one cell area CELL in the second horizontal direction (the Y direction).

In some embodiments, each of the memory cell blocks BLK1, BLK2, BLK3, and BLK4 may further include a peripheral connection area PA. The peripheral connection area PA may be arranged on at least one of both sides of the cell area CELL in the second horizontal direction (the Y direction). For example, components for connecting the peripheral circuit structure PS described with reference to FIG. 2 to and the cell area CELL and/or the cell connection area EXT may be arranged in the peripheral connection area PA. Alternatively, for example, the peripheral connection area PA may include at least a portion of the peripheral circuit 30 described with reference to FIG. 1.

The peripheral connection area PA illustrated in FIG. 4A may show only a portion of the peripheral connection area PA illustrated in FIG. 4B adjacent to the edge area ER of the nonvolatile memory device 1. For example, the cell area CELL illustrated in FIG. 4A may include at least a portion of the cell area CELL and the cell connection area EXT of each of the memory cell blocks BLK1, BLK2, BLK3, and BLK4 illustrated in FIG. 4B and the peripheral connection area PA of each of the memory cell blocks BLK1, BLK2, BLK3, and BLK4 illustrated in FIG. 4B.

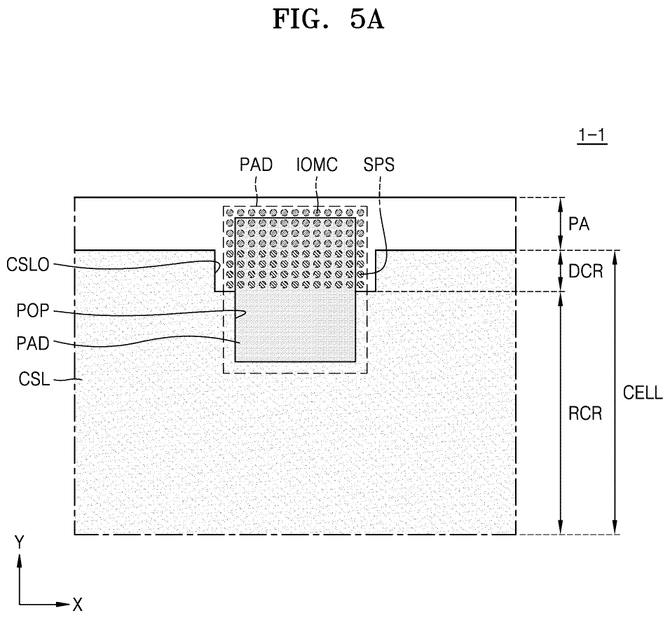

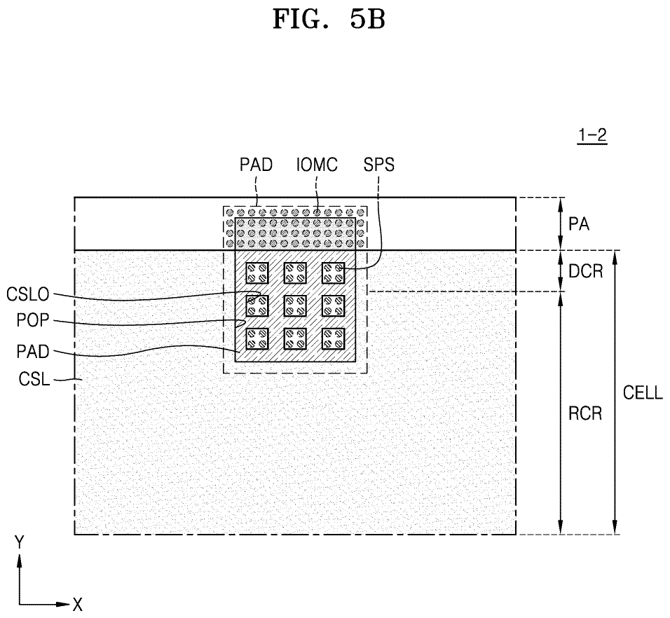

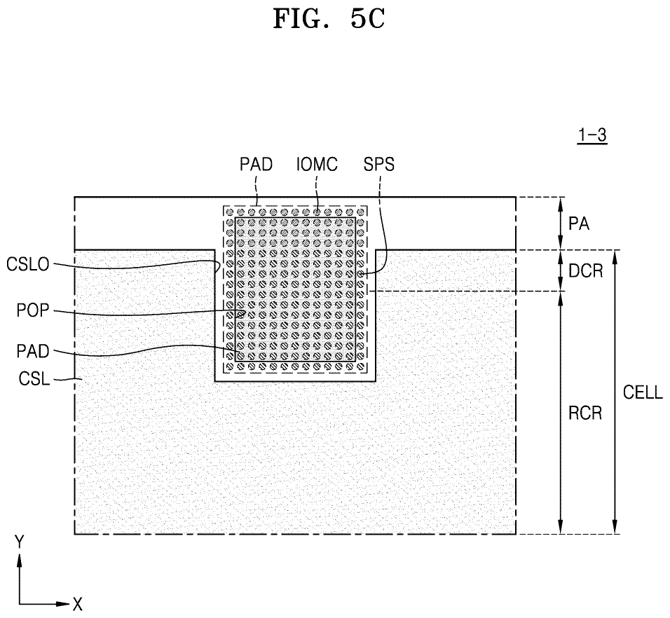

FIGS. 5A to 5C are schematic plan views of nonvolatile memory devices according to embodiments.

Referring to FIG. 5A, a nonvolatile memory device 1-1 may include a cell area CELL and a peripheral connection area PA adjacent to the cell area CELL in a plan view. The peripheral connection area PA illustrated in FIG. 5A may be adjacent to the edge area ER illustrated in FIG. 4A. The cell area CELL may include a real cell area RCR and a dummy cell area DCR adjacent to the real cell area RCR. The dummy cell area DCR may be arranged along the edge of the cell area CELL so as to surround the real cell area RCR in a plan view. For example, the dummy cell area DCR may be between the real cell area RCR and the peripheral connection area PA.

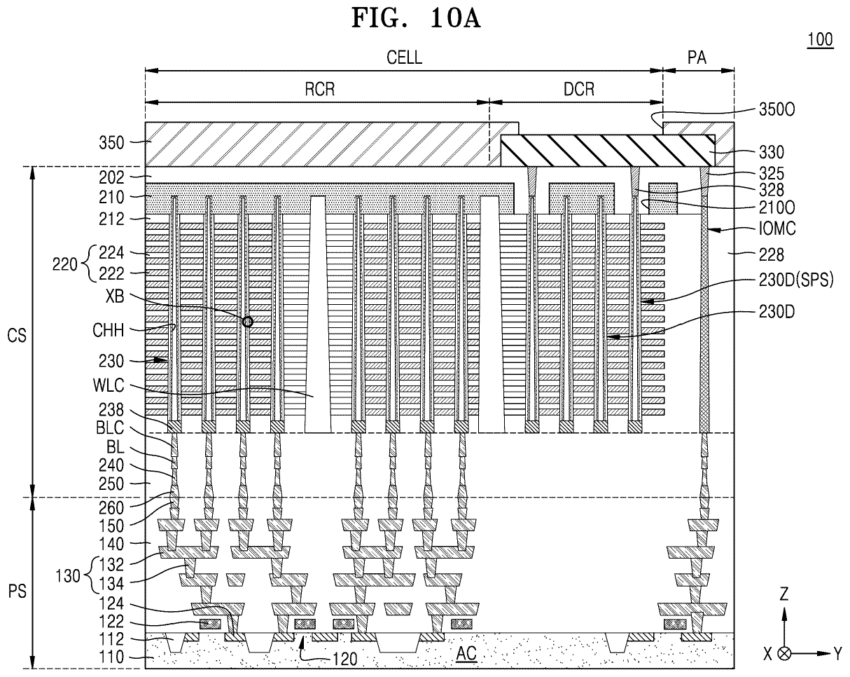

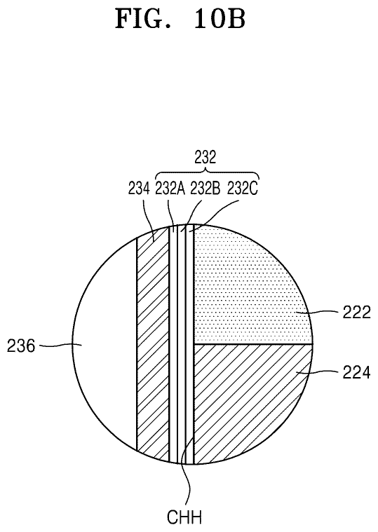

A pad pattern PAD may extend from the peripheral connection area PA to the cell area CELL in the second horizontal direction (Y direction) so as to be located across the peripheral connection area PA and the cell area CELL. For example, a portion of the pad pattern PAD may be located in the peripheral connection area PA and another portion of the pad pattern PAD may be located in the cell area CELL. In the cell area CELL, the pad pattern PAD may extend across the dummy cell area DCR and the real cell area RCR. For example, the pad pattern PAD may extend in the second horizontal direction across the peripheral connection area PA, the dummy cell area DCR, and the real cell area RCR. The edge portion of the pad pattern PAD may be covered with a protective layer (not shown) (e.g., see 350 of FIG. 10A). The term “covered” (or “covering,” “covers,” or like terms), as may be used herein, is intended to broadly refer to an element, structure or layer that is on or over another element, structure or layer, either directly or with one or more other intervening elements, structures or layers therebetween. The protective layer (see 350 of FIG. 10A) may have a pad opening POP (see 3500 of FIG. 10A). At least a portion of the pad pattern PAD may be exposed to the outside of the nonvolatile memory device 1-1 through the pad opening POP. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

A common source line layer CSL may be arranged in at least a portion of the cell area CELL. The common source line layer CSL may be the common source line CSL illustrated in FIG. 3. In a plan view, a portion of the pad pattern PAD may vertically overlap the common source line layer CSL. The common source line layer CSL may have a common source opening CSLO. The common source opening CSLO may be formed by removing a portion of the common source line layer CSL from a portion of the cell area CELL adjacent to the peripheral connection area PA. For example, the common source line layer CSL may not be located in the peripheral connection area PA and may be located only in the cell area CELL. The common source opening CSLO may be located in the cell area CELL adjacent to the peripheral connection area PA. In a plan view, the common source opening CSLO may be located at the edge of the common source line layer CSL. In some embodiments, the common source opening CSLO may be located in the dummy cell area DCR and may not be located in the real cell area RCR. At least a portion of the common source opening CSLO may overlap the pad pattern PAD in the vertical direction (the Z direction).

In the peripheral connection area PA, at least one through-contact plug IOMC may be disposed under the pad pattern PAD. In the cell area CELL, at least one support structure SPS may be disposed under the pad pattern PAD. The at least one support structure SPS may overlap the common source opening CSLO in the vertical direction (the Z direction). In a plan view, the support structure SPS may be located in the dummy cell area DCR and may not be located in the real cell area RCR. Although FIG. 5A illustrates that a plurality of support structures SPS overlap one common source opening CSLO in the vertical direction (the Z direction), this is only an example and the inventive concept is not limited thereto. For example, the common source line layer CSL may have a plurality of common source openings CSLO. Each of the common source openings CSLO may overlap the at least one support structure SPS in the vertical direction (the Z direction).

Although FIG. 5A illustrates that the through-contact plugs IOMC are all arranged in the peripheral connection area PA and the support structures SPS are all arranged in the dummy cell area DCR, the inventive concept is not limited thereto. For example, some of the through-contact plugs IOMC may be arranged in the peripheral connection area PA and at least one other through-contact plug IOMC may be arranged in the dummy cell area DCR. For example, some of the support structures SPS may be arranged in the dummy cell area DCR and at least one other support structure SPS may be arranged in the peripheral connection area PA.

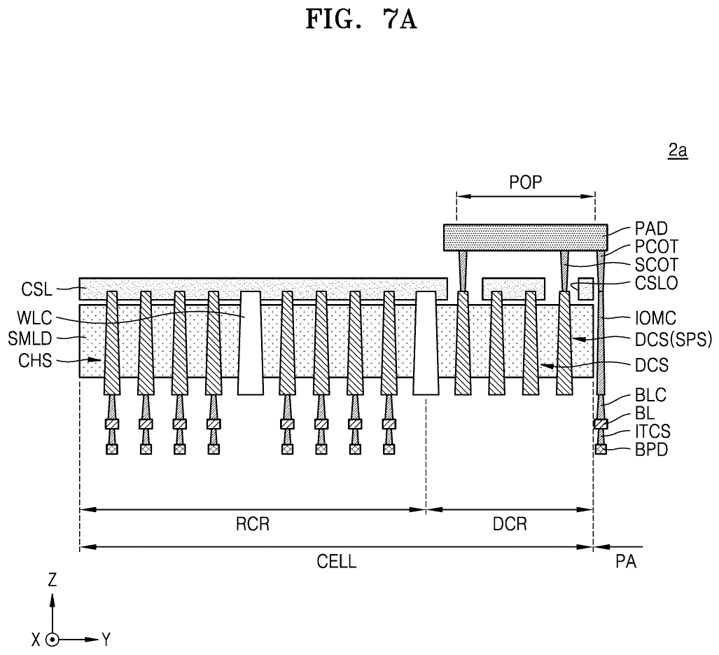

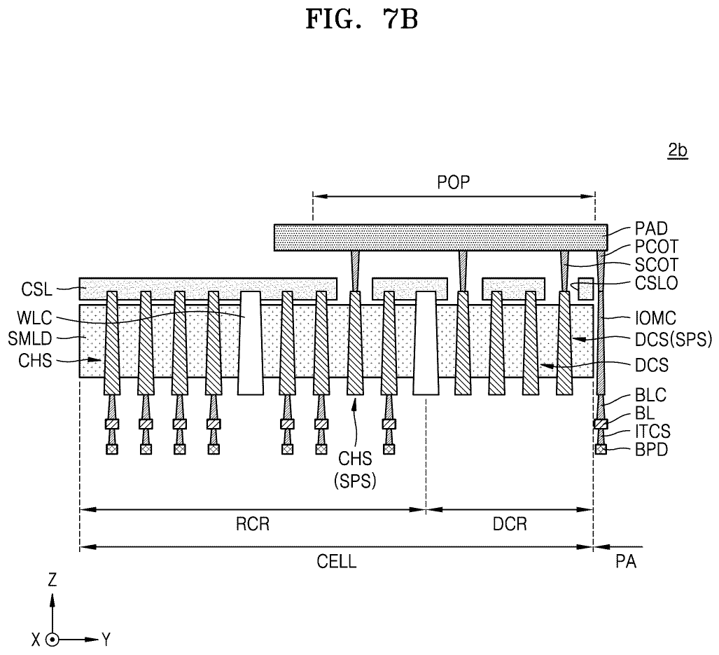

In some embodiments, unlike those illustrated in FIG. 5A, the pad pattern PAD may be located only in the dummy cell area DCR in the cell area CELL. For example, as illustrated in FIG. 7A, the pad pattern PAD may be located across the peripheral connection area PA and the dummy cell area DCR. In some embodiments, the pad pattern PAD may not overlap the common source line layer CSL in a plan view.

Referring to FIG. 5B, a nonvolatile memory device 1-2 may include a cell area CELL and a peripheral connection area PA adjacent to the cell area CELL in a plan view. The cell area CELL may include a real cell area RCR and a dummy cell area DCR adjacent to the real cell area RCR. A pad pattern PAD may extend in the second horizontal direction (Y direction) from the peripheral connection area PA to the cell area CELL so as to be located across the peripheral connection area PA and the cell area CELL. In the cell area CELL, the pad pattern PAD may be located across the dummy cell area DCR and the real cell area RCR. A common source line layer CSL may be arranged in the cell area CELL. In a plan view, a portion of the pad pattern PAD may overlap the common source line layer CSL.

The common source line layer CSL may have a plurality of common source openings CSLO that are spaced apart from each other in the first horizontal direction (X direction) and/or the second horizontal direction (Y direction). A plurality of common source openings CSLO may be formed by removing portions of the common source line CSL from portions of the cell area CELL adjacent to the peripheral connection area PA. In some embodiments, some of the common source openings CSLO may be located in the dummy cell area DCR and others thereof may be located in the real cell area RCR. For example, in a plan view, some of a plurality of support structures SPS may be located in the dummy cell area DCR and others thereof may be located in the real cell area RCR. At least some of the common source openings CSLO may be spaced apart from the edge of the common source line layer CSL.

In the cell area CELL, the support structures SPS may be disposed under the pad pattern PAD. Each of the support structures SPS may overlap one of the common source openings CSLO in the vertical direction (the Z direction). For example, each of the common source openings CSLO may overlap at least one support structure SPS in the vertical direction (the Z direction).

Referring to FIG. 5C, a nonvolatile memory device 1-3 may include a cell area CELL and a peripheral connection area PA adjacent to the cell area CELL in a plan view. A pad pattern PAD may extend in the second horizontal direction (Y direction) from the peripheral connection area PA to the cell area CELL so as to be located across the peripheral connection area PA and the cell area CELL. In the cell area CELL, the pad pattern PAD may be located across the dummy cell area DCR and the real cell area RCR. A common source line layer CSL may be arranged in the cell area CELL. In a plan view, the pad pattern PAD may not overlap the common source line layer CSL in the vertical direction. The common source line layer CSL may have a common source opening CSLO. The common source opening CSLO may be formed by removing a portion of the common source line CSL from a portion of the cell area CELL adjacent to the peripheral connection area PA. The common source opening CSLO may be located in the cell area CELL adjacent to the peripheral connection area PA. In a plan view, the common source opening CSLO may be located at the edge of the common source line layer CSL. The common source opening CSLO may extend in the second horizontal direction (Y direction) across the dummy cell area DCR and the real cell area RCR.

In the cell area CELL, the support structures SPS may be disposed under the pad pattern PAD. The support structure SPS may overlap the common source opening CSLO in the vertical direction (the Z direction). Some of the support structures SPS may be arranged in the dummy cell area DCR and others thereof may be arranged in the real cell area RCR.

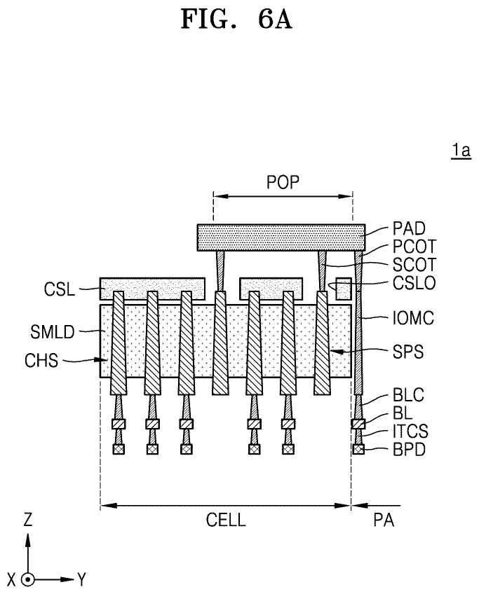

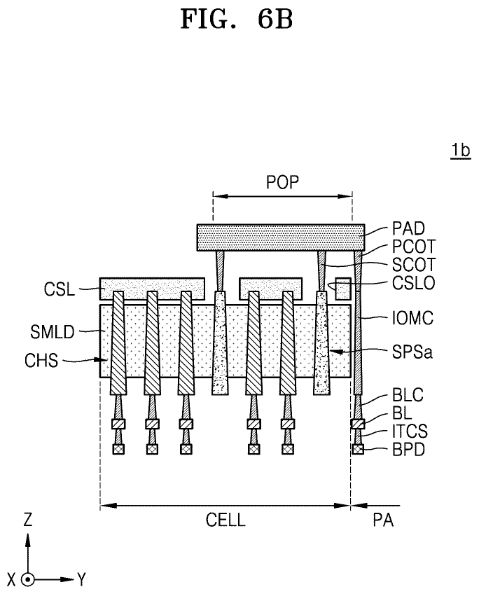

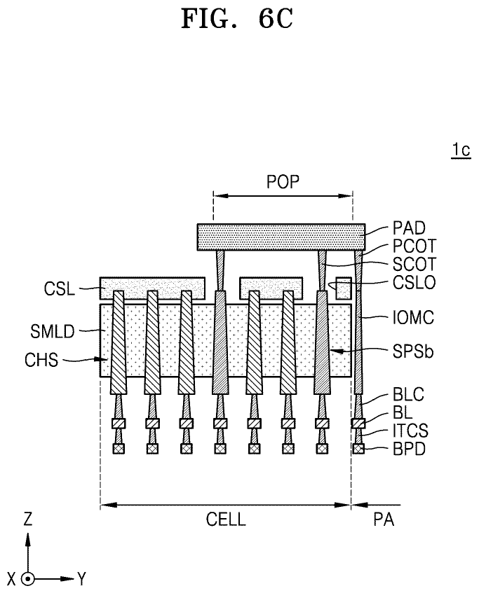

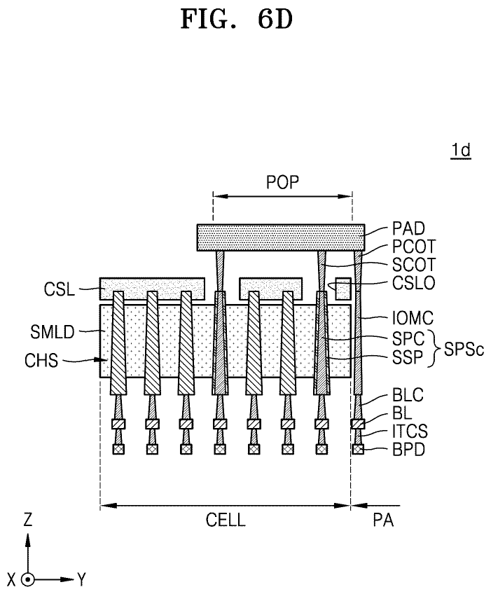

FIGS. 6A to 6D are schematic cross-sectional views of example nonvolatile memory devices according to some embodiments.

Referring to FIG. 6A, a nonvolatile memory device 1a may include a cell area CELL and a peripheral connection area PA adjacent to the cell area CELL. The peripheral connection area PA illustrated in FIG. 6A may be adjacent to the edge area ER illustrated in FIG. 4A. In some embodiments, the cell area CELL may include the real cell area RCR illustrated in FIGS. 5A to 5C.

A pad pattern PAD may extend in the second horizontal direction (Y direction) from the peripheral connection area PA to the cell area CELL so as to be located across the peripheral connection area PA and the cell area CELL. The pad pattern PAD may be exposed to the outside of the nonvolatile memory device 1a through a pad opening POP that vertically overlaps at least a portion of the pad pattern PAD. A stacked mold SMLD and a common source line layer CSL disposed on the stacked mold SMLD may be arranged in the cell area CELL. The stacked mold SMLD and the common source line layer CSL may be arranged in the cell area CELL and may not be arranged in the peripheral connection area PA. A plurality of cell channel structures CHS may penetrate through (i.e., extend at least partially into) the stacked mold SMLD and extend in the vertical direction (the Z direction) so as to be connected to the common source line layer CSL. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

The common source line layer CSL may have at least one common source opening CSLO. At least one common source opening CSLO may extend from the upper surface to the lower surface of the common source line layer CSL. At least one support structure SPS may penetrate through (i.e., extend at least partially into) the stacked mold SMLD and extend into the at least one common source opening CSLO. The at least one support structure SPS may overlap the pad pattern PAD in the vertical direction (the Z direction). In some embodiments, the common source line layer CSL may have a plurality of common source openings CSLO that are spaced apart from each other in the first horizontal direction (X direction) and/or the second horizontal direction (Y direction). Although FIG. 6A illustrates that one support structure SPS penetrates through the stacked mold SMLD and extends into the common source openings CSLO, the inventive concept is not limited thereto. For example, two or more support structures SPS may penetrate through the stacked mold SMLD and extend into the common source openings CSLO.

In the peripheral connection area PA, at least one through-contact plug IOMC may be disposed under the pad pattern PAD. The pad pattern PAD may overlap the at least one through-contact plug IOMC and the at least one support structure SPS in the vertical direction (the Z direction). In some embodiments, the pad pattern PAD may overlap some of the cell channel structures CHS in the vertical direction (the Z direction) and may not overlap the others thereof. In some embodiments, the pad pattern PAD may not overlap all the cell channel structures CHS in the vertical direction (the Z direction).

A pad connection via PCOT may be between the pad pattern PAD and the through-contact plug IOMC. The upper and lower surfaces of the pad connection via PCOT may be in contact with the lower surface of the pad pattern PAD and the upper surface of the through-contact plug IOMC, respectively. A pad support via SCOT may be between the pad pattern PAD and the support structure SPS. The upper and lower surfaces of the pad support via SCOT may be in contact with the lower surface of the pad pattern PAD and the upper surface of the support structure SPS, respectively.

The cell channel structures CHS and the at least one through-contact plug IOMC may be electrically connected to an upper bonding pad BPD. The cell channel structures CHS and the at least one through-contact plug IOMC may be electrically connected through the upper bonding pad BPD to the peripheral circuit structure PS illustrated in FIG. 2. The cell channel structures CHS and the at least one through-contact plug IOMC may be electrically connected to a bit line BL. The cell channel structures CHS and the at least one through-contact plug IOMC may be electrically connected to the bit line BL through a bit line contact BLC. The bit line BL may be electrically connected to the upper bonding pad BPD through an upper interconnect structure ITCS. For example, the bit line contact BLC, the bit line BL, and the upper interconnect structure ITCS may be sequentially arranged between each of the cell channel structures CHS and the at least one through-contact plug IOMC and the upper bonding pad BPD.

Although FIG. 6A illustrates that the upper interconnect structure ITCS is one contact, this is only an example and the inventive concept is not limited thereto. For example, the upper interconnect structure ITCS may include one or more contacts and one or more wiring layers. In some embodiments, the contact plug, the bit line contact BLC, and the through-contact plug IOMC, which are included in the upper interconnect structure ITCS, may each have a tapered shape in which the horizontal width thereof decreases when extending vertically from the lower side to the upper side. In some embodiments, the pad connection via PCOT and the pad support via SCOT may each have a tapered shape in which the horizontal width thereof increases when extending vertically from the lower side to the upper side.

The support structure SPS may not be electrically connected to the upper bonding pad BPD. The support structure SPS may not be electrically connected to the bit line BL. For example, the bit line contact BLC may be connected to the lower surface of each of the cell channel structures CHS and the at least one through-contact plug IOMC, but the bit line contact BLC may not be connected to the lower surface of the support structure SPS.

In some embodiments, at least a portion of the cell channel structure CHS and at least a portion of the support structure SPS may be formed together through the same manufacturing process. For example, the support structure SPS may have a structure identical to or substantially similar to the cell channel structure CHS. The cell channel structure CHS is described in detail with reference to FIGS. 10A and 10B. The pad connection via PCOT and the pad support vias SCOT may be formed together through the same manufacturing process. For example, the pad connection via PCOT and the pad support via SCOT may include the same material and have the same structure. In some embodiments, the pad connection via PCOT and the pad support via SCOT may include metal.

The nonvolatile memory device 1a according to the inventive concept may include the support structure SPS disposed under the pad pattern PAD, and the pad support via SCOT between the support structure SPS and the pad pattern PAD. Accordingly, even when a load is applied to the pad pattern PAD during a wire bonding process of connecting a bonding wire to the upper surface of the pad pattern PAD exposed through the pad opening POP, the pad pattern PAD may be supported by the support structure SPS and the pad support via SCOT. Therefore, the nonvolatile memory device 1a according to the inventive concept may have structural reliability to prevent damage to the pad pattern PAD, the common source line layer CSL, the stacked mold SMLD, and/or the cell channel structures CHS due to the load applied to the pad pattern PAD during the wire bonding process even when the pad pattern PAD is located on the cell area CELL.

Referring to FIG. 6B, the nonvolatile memory device 1b may include a support structure SPSa instead of the support structure SPS illustrated in FIG. 6A. The support structure SPSa may include a material that is different from the cell channel structure CHS and may have a structure that is different than the cell channel structure CHS. For example, the support structure SPSa may include polysilicon or a carbon-containing material. After a plurality of channel holes (see CHH of FIGS. 10A and 10B) penetrating through (i.e., extending at least partially into) the stacked mold SMLD are formed, a plurality of sacrificial layers filling the channel holes CHH may be formed. The term “filling” (or “fills,” “filled,” or like terms), as may be used herein, is intended to refer broadly to either completely filling a defined space (e.g., the channel holes CHH) or partially filling the defined space; that is, the defined space need not be entirely filled but may, for example, be partially filled or have voids or other spaces throughout. The support structure SPSA may be formed by leaving the sacrificial layers filling some of the channel holes CHH without being removed. After the sacrificial layers filling some of the channel holes CHH are removed, the cell channel structure CHS may be formed by filling others of the channel holes CHH.

Referring to FIG. 6C, a nonvolatile memory device 1c may include a support structure SPSb instead of the support structure SPS illustrated in FIG. 6A. The support structure SPSb may include a material that is different from the cell channel structure CHS and may have a structure that is different than the cell channel structure CHS. The support structure SPSb may include a metal-based material. For example, the support structure SPSb may include metal, such as tungsten, nickel, cobalt, and tantalum, a conductive metal nitride, such as titanium nitride, tantalum nitride, and tungsten nitride, a metal silicide, such as tungsten silicide, nickel silicide, cobalt silicide, and tantalum silicide, or any combination thereof, although embodiments are not limited thereto.

In some embodiments, the support structure SPSb may be electrically connected to the upper bonding pad BPD to electrically connect the pad pattern PAD to the peripheral circuit structure PS illustrated in FIG. 2 together with the through-contact plug IOMC. For example, a bit line contact BLC, a bit line BL, and an upper interconnect structure ITCS may be sequentially between the support structure SPSb and the upper bonding pad BPD. In other embodiments, like the support structure SPS illustrated in FIG. 6A or the support structure SPSa illustrated in FIG. 6B, the support structure SPSb may not be electrically connected to the upper bonding pad BPD and the bit line contact BLC may not be connected to the lower surface of the support structure SPSb.

Referring to FIG. 6D, a nonvolatile memory device 1d may include a support structure SPSc instead of the support structure SPSb illustrated in FIG. 6C. The support structure SPSc may include a material that is different from the cell channel structure CHS and may have a structure that is different than the cell channel structure CHS. The support structure SPSc may include a support core layer SPC and a support spacer layer SSP surrounding the support core layer SPC. Similar to the support structure SPSb illustrated in FIG. 6C, the support core layer SPC may include a metal-based material. The support spacer layer SSP may be between the support core layer SPC and the stacked mold SMLD so that the support core layer SPC is electrically isolated from the stacked mold SMLD. The support spacer layer SSP may include an insulating material. For example, the support spacer layer SSP may include nitride, oxide, oxynitride, or any combination thereof, although embodiments are not limited thereto.

In some embodiments, the support core layer SPC may be electrically connected to the upper bonding pad BPD to electrically connect the pad pattern PAD to the peripheral circuit structure PS illustrated in FIG. 2 together with the through-contact plug IOMC. For example, a bit line contact BLC, a bit line BL, and an upper interconnect structure ITCS may be sequentially between the support core layer SPC and the upper bonding pad BPD. In other embodiments, like the support structure SPS illustrated in FIG. 6A or the support structure SPSa illustrated in FIG. 6B, the support core layer SPC may not be electrically connected to the upper bonding pad BPD and the bit line contact BLC may not be connected to the lower surface of the support core layer SPC.

FIGS. 7A and 7B are schematic cross-sectional views of example nonvolatile memory devices according to embodiments.

Referring to FIG. 7A, a nonvolatile memory device 2a may include a cell area CELL and a peripheral connection area PA adjacent to the cell area CELL. The peripheral connection area PA illustrated in FIG. 7A may be adjacent to the edge area ER illustrated in FIG. 4A; that is, the peripheral connection area PA may be disposed between the edge area ER and the cell area CELL in plan view. The cell area CELL may include a real cell area RCR and a dummy cell area DCR. The dummy cell area DCR may be between the real cell area RCR and the peripheral connection area PA.

A pad pattern PAD may extend in the second horizontal direction (Y direction) from the peripheral connection area PA to the dummy cell area DCR so as to be located across the peripheral connection area PA and the dummy cell area DCR. The pad pattern PAD may be exposed to the outside of the nonvolatile memory device 2a through a pad opening POP. A stacked mold SMLD and a common source line layer CSL disposed on the stacked mold SMLD may be arranged in the cell area CELL. The stacked mold SMLD and the common source line layer CSL may be arranged in the cell area CELL and may not be arranged in the peripheral connection area PA.

The common source line layer CSL may have at least one common source opening CSLO. A plurality of cell channel structures CHS may be arranged in the real cell area RCR and a plurality of dummy structures DCS may be arranged in the dummy cell area DCR. The plurality of cell channel structures CHS may penetrate through the stacked mold SMLD and extend in the vertical direction (the Z direction) so as to be connected to the common source line layer CSL. Some of the dummy structures DCS may penetrate through the stacked mold SMLD and extend in the vertical direction (the Z direction) so as to be connected to the common source line layer CSL, and others of the dummy structures DCS may penetrate through the stacked mold SMLD and extend into the at least one common source opening CSLO. At least some of the dummy structures DCS may overlap the pad pattern PAD in the vertical direction (the Z direction). Others of the dummy structures DCS penetrating through the stacked mold SMLD and extending into the at least one common source opening CSLO may perform the function of the support structure SPS illustrated in FIG. 6A. Others of the dummy structures DCS that perform the function of the support structure SPS may overlap the pad pattern PAD in the vertical direction (the Z direction).

In some embodiments, the nonvolatile memory device 2a may further include a word line cut area WLC penetrating through the stacked mold SMLD. The word line cut area WLC may be spaced apart from the cell channel structures CHS. In some embodiments, the word line cut area WLC may extend in the first horizontal direction (the X direction) along between the cell channel structures CHS adjacent to each other in the second horizontal direction (the Y direction). The word line cut area WLC may include an oxide layer, a nitride layer, or any combination thereof, although embodiments are not limited thereto.

In some embodiments, at least a portion of the cell channel structure CHS and at least a portion of the dummy structure DCS may be formed together through the same manufacturing process. For example, the dummy structure DCS may have a structure identical to or substantially similar to the cell channel structure CHS. In some embodiments, all the dummy structures DCS or others of the dummy structures DCS that perform the function of the support structure SPS may have the same structure as one of the support structure SPS illustrated in FIG. 6A, the support structure SPSa illustrated in FIG. 6B, the support structure SPSb illustrated in FIG. 6C, and the support structure SPSc illustrated in FIG. 6D.

In some embodiments, others of the dummy structures DCS that perform the function of the support structure SPS may not be electrically connected to the upper bonding pad BPD. For example, the bit line contact BLC may not be connected to the lower surfaces of others of the dummy structures DCS that perform the function of the support structure SPS.

In some embodiments, when the dummy structure DCS has the same structure as the support structure SPSb illustrated in FIG. 6C or the support structure SPSc illustrated in FIG. 6D, the dummy structure DCS may be electrically connected to the upper bonding pad BPD to electrically connect the pad pattern PAD to the peripheral circuit structure PS illustrated in FIG. 2 together with the through-contact plug IOMC.

Referring to FIG. 7B, a nonvolatile memory device 2b may include a cell area CELL and a peripheral connection area PA adjacent to the cell area CELL. The peripheral connection area PA illustrated in FIG. 7B may be adjacent to the edge area ER illustrated in FIG. 4A. The cell area CELL may include a real cell area RCR and a dummy cell area DCR.

A pad pattern PAD may extend from the peripheral connection area PA to the real cell area RCR through the dummy cell area DCR so as to be located across the peripheral connection area PA, the dummy cell area DCR, and the real cell area RCR. The pad pattern PAD may be exposed to the outside of the nonvolatile memory device 2b through a pad opening POP. A stacked mold SMLD and a common source line layer CSL disposed on the stacked mold SMLD may be arranged in the cell area CELL.

The common source line layer CSL may have at least one common source opening CSLO. A plurality of cell channel structures CHS may be arranged in the real cell area RCR and a plurality of dummy structures DCS may be arranged in the dummy cell area DCR. Some of the cell channel structures CHS may penetrate through the stacked mold SMLD and extend in the vertical direction (the Z direction) so as to be connected to the common source line layer CSL. Some of the dummy structures DCS may penetrate through the stacked mold SMLD and extend in the vertical direction (the Z direction) so as to be connected to the common source line layer CSL. Others of the cell channel structures CHS and others of the dummy structures DCS may each penetrate through the stacked mold SMLD and extend into the at least one common source opening CSLO. Some of the cell channel structures CHS and at least some of the dummy structures DCS may overlap the pad pattern PAD in the vertical direction (the Z direction). Others of the cell channel structures CHS and others of the dummy structures DCS, which each penetrate through the stacked mold SMLD and extend into the at least one common source opening CSLO, may perform the function of the support structure SPS illustrated in FIG. 6A. Others of the cell channel structures CHS and others of the dummy structures DCS that perform the function of the support structure SPS may overlap the pad pattern PAD in the vertical direction (the Z direction).

In some embodiments, others of the cell channel structures CHS and others of the dummy structures DCS that perform the function of the support structure SPS may not be electrically connected to the upper bonding pad BPD. For example, the bit line contact BLC may not be connected to the lower surface of each of others of the cell channel structures CHS and others of the dummy structures DCS that perform the function of the support structure SPS.

In some embodiments, at least a portion of the cell channel structure CHS and at least a portion of the dummy structure DCS may be formed together through the same manufacturing process. For example, the dummy structure DCS may have a structure identical to or substantially similar to the cell channel structure CHS. In some embodiments, all the dummy structures DCS or others of the cell channel structures CHS and others of the dummy structures DCS that perform the function of the support structure SPS may have the same structure as one of the support structure SPS illustrated in FIG. 6A, the support structure SPSa illustrated in FIG. 6B, the support structure SPSb illustrated in FIG. 6C, and the support structure SPSc illustrated in FIG. 6D.

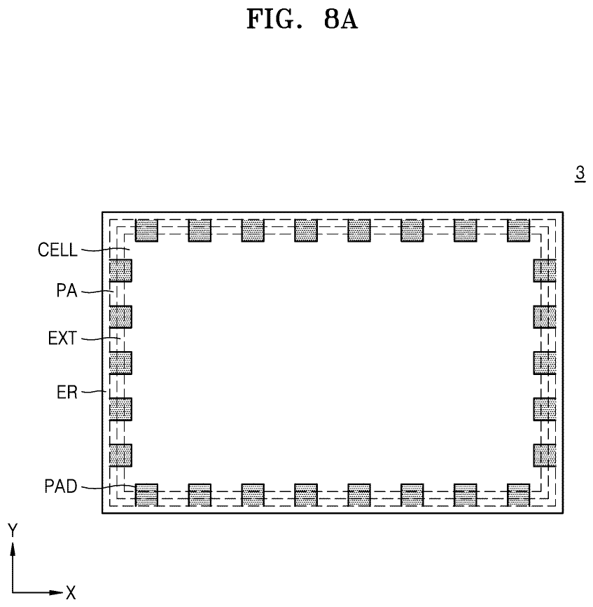

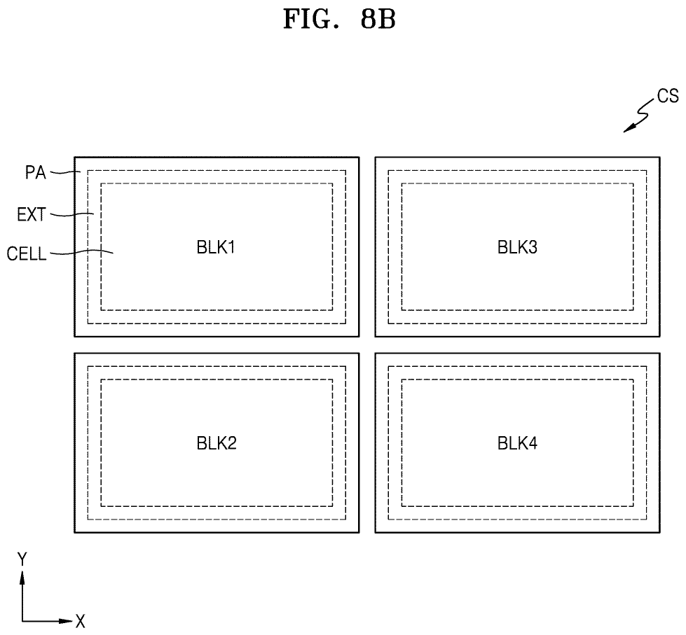

FIGS. 8A and 8B are schematic plan view layout diagrams of a nonvolatile memory device 3 according to one or more embodiments.

Referring to FIG. 8A, the nonvolatile memory device 3 may include a cell area CELL and an edge area ER surrounding the cell area CELL in a plan view. A peripheral connection area PA may be between the cell area CELL and the edge area ER. In some embodiments, the peripheral connection area PA may be between the cell area CELL and the edge area ER in the second horizontal direction (the Y direction) and extend in the first horizontal direction (the X direction), and may be between the cell area CELL and the edge area ER in the first horizontal direction (the X direction) and extend in the second horizontal direction (the Y direction). Therefore, the peripheral connection area PA may surround the cell area CELL in a plan view. A cell connection area EXT may be between the cell area CELL and the peripheral connection area PA. In some embodiments, the cell connection area EXT may be between the cell area CELL and the peripheral connection area PA in the second horizontal direction (the Y direction) and extend in the first horizontal direction (the X direction), and may be between the cell area CELL and the peripheral connection area PA in the first horizontal direction (the X direction) and extend in the second horizontal direction (the Y direction). Therefore, the cell connection area PA may surround the cell area CELL in a plan view. For example, the cell connection area EXT may surround the cell area CELL in a plan view, the peripheral connection area PA may surround the cell connection area EXT in a plan view, and the edge area ER may surround the peripheral connection area PA in a plan view.

The nonvolatile memory device 3 may include a plurality of pad patterns PAD. In some embodiments, the pad patterns PAD may be arranged adjacent to both sides of the edge area ER opposite to each other in the second horizontal direction (the Y direction) and both sides of the edge area ER opposite to each other in the first horizontal direction (the X direction). For example, the pad patterns PAD may be arranged to surround the cell area CELL in a plan view. In some embodiments, the pad patterns PAD may be arranged adjacent only to both sides of the edge area ER opposite to each other in the second horizontal direction (the Y direction), or may be arranged adjacent only to both sides of the edge area ER opposite to each other in the first horizontal direction (the X direction). The pad patterns PAD may be arranged to form a row along the peripheral connection area PA. In some embodiments, the pad patterns PAD may be arranged to form a row in the first horizontal direction (the X direction), or may be arranged to form a row in the second horizontal direction (the Y direction). Each of the pad patterns PAD may be located across the peripheral connection area PA and the cell connection area EXT, or may be located across at least portions of the peripheral connection area PA, the cell connection area EXT, and the cell area CELL.

Referring to FIGS. 8A and 8B together, the nonvolatile memory device 3 may include a cell array structure CS. The nonvolatile memory device 3 may be the nonvolatile memory device 10 illustrated in FIG. 1 and the cell array structure CS may be the cell array structure CS illustrated in FIG. 2.

The cell array structure CS may include a plurality of memory cell blocks BLK1, BLK2, BLK3, and BLK4. Each of the memory cell blocks BLK1, BLK2, BLK3, and BLK4 may include a cell area CELL and a cell connection area EXT. In some embodiments, each of the memory cell blocks BLK1, BLK2, BLK3, and BLK4 may include one cell area CELL and a cell connection area EXT surrounding the one cell area CELL in a plan view. A pair of cell connection areas EXT may extend in the second horizontal direction (the Y direction) from both (opposing) sides of the one cell area CELL in the first horizontal direction (the X direction), and may extend in the first horizontal direction (the X direction) from opposing sides of one cell area CELL in the second horizontal direction (the Y direction).

In some embodiments, each of the memory cell blocks BLK1, BLK2, BLK3, and BLK4 may further include a peripheral connection area PA. The peripheral connection area PA may be arranged to surround the cell area CELL and the cell connection area EXT in a plan view, but the inventive concept is not limited thereto. For example, the peripheral connection area PA may be arranged on both (opposing) sides of the cell area CELL in the second horizontal direction (the Y direction), or may be arranged on both sides of the cell area CELL in the first horizontal direction (the X direction).

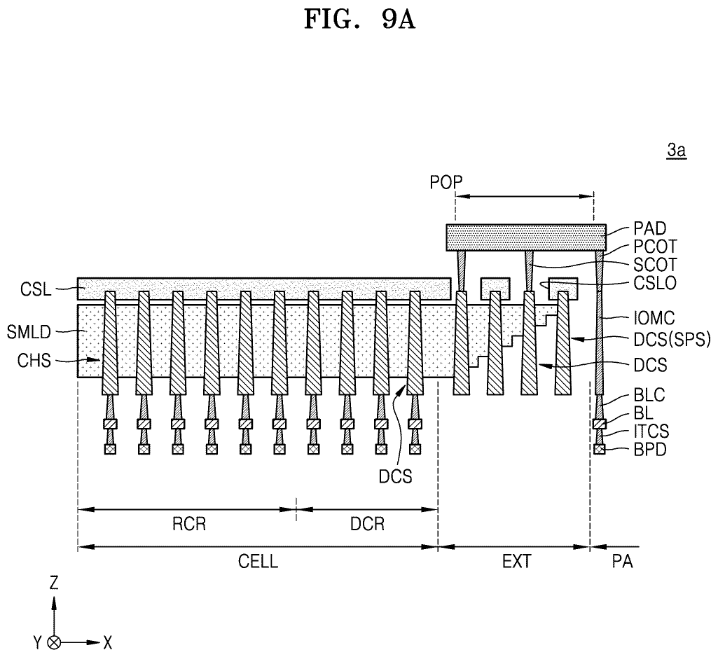

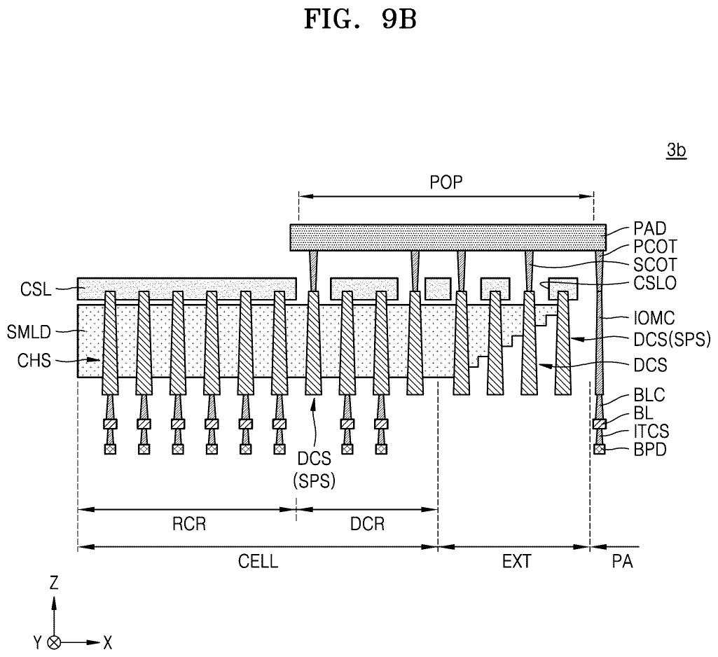

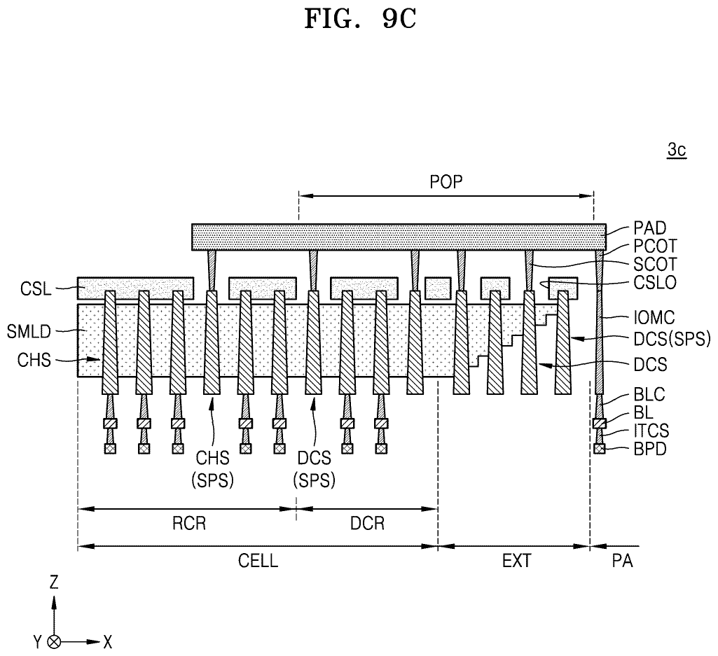

FIGS. 9A to 9C are schematic cross-sectional views of nonvolatile memory devices according to embodiments.

Referring to FIG. 9A, a nonvolatile memory device 3a may include a cell area CELL, a peripheral connection area PA, and a cell connection area EXT between the cell area CELL and the peripheral connection area PA. The peripheral connection area PA illustrated in FIG. 9A may be adjacent to the edge area ER illustrated in FIG. 8A. The cell area CELL may include a real cell area RCR and a dummy cell area DCR adjacent to the real cell area RCR. The dummy cell area DCR may be between the real cell area RCR and the cell connection area EXT.

A pad pattern PAD may extend in the first horizontal direction (X direction) from the peripheral connection area PA to the cell connection area EXT so as to extend laterally (i.e., in a horizontal direction) across at least a portion of the peripheral connection area PA and the cell connection area EXT. At least a portion of the pad pattern PAD may be exposed to the outside of the nonvolatile memory device 3a through a pad opening POP. A stacked mold SMLD and a common source line layer CSL disposed on the stacked mold SMLD may be arranged in the cell area CELL and the cell connection area EXT. The stacked mold SMLD and the common source line layer CSL may be arranged in the cell area CELL and the cell connection area EXT and may not be arranged in the peripheral connection area PA. The stacked mold SMLD may form a stepped structure in the vertical direction (Z direction) in the cell connection area EXT.

The common source line layer CSL may have at least one common source opening CSLO. A plurality of cell channel structures CHS may be arranged in the real cell area RCR and a plurality of dummy structures DCS may be arranged in the dummy cell area DCR and the cell connection area EXT. The plurality of cell channel structures CHS may penetrate through the stacked mold SMLD and extend in the vertical direction (the Z direction) so as to be connected to the common source line layer CSL. The dummy structures DCS arranged in the dummy cell area DCR may penetrate through the stacked mold SMLD and extend in the vertical direction (the Z direction) so as to be connected to the common source line layer CSL. Some of the dummy structures DCS arranged in the cell connection area EXT may penetrate through the stacked mold SMLD and extend in the vertical direction (the Z direction) so as to be connected to the common source line layer CSL, and others thereof may penetrate through the stacked mold SMLD and extend into the at least one common source opening CSLO. The dummy structures DCS arranged in the cell connection area EXT may overlap the pad pattern PAD in the vertical direction (the Z direction). The dummy structures DCS penetrating through the stacked mold SMLD and extending into the at least one common source opening CSLO may perform the function of the support structure SPS illustrated in FIG. 6A.

Although FIG. 9A illustrates that the cell area CELL, the cell connection area EXT, and the peripheral connection area PA are arranged in the first horizontal direction (the X direction), the inventive concept is not limited thereto. For example, the cell area CELL, the cell connection area EXT, and the peripheral connection area PA may be arranged in the second horizontal direction (the Y direction).

In some embodiments, at least a portion of the cell channel structure CHS and at least a portion of the dummy structure DCS may be formed together through the same manufacturing process. For example, the dummy structure DCS may have a structure identical to or substantially similar to the cell channel structure CHS. In some embodiments, all the dummy structures DCS or the dummy structures DCS that perform the function of the support structure SPS may have the same structure as one of the support structures SPS illustrated in FIG. 6A, the support structure SPSa illustrated in FIG. 6B, the support structure SPSb illustrated in FIG. 6C, and the support structure SPSc illustrated in FIG. 6D.

Although FIG. 9A illustrates that the dummy structures DCS arranged in the dummy cell area DCR are electrically connected to the upper bonding pad BPD and the dummy structures DCS arranged in the cell connection area EXT are not electrically connected to the upper bonding pad BPD, the inventive concept is not limited thereto. In some embodiments, none of the dummy structures DCS arranged in the dummy cell area DCR and the cell connection area EXT may be electrically connected to the upper bonding pad BPD. In some embodiments, the dummy structures DCS that perform the function of the support structure SPS may not be electrically connected to the upper bonding pad BPD, and the remaining dummy structures DCS may be electrically connected to the upper bonding pad BPD.

Referring to FIG. 9B, a nonvolatile memory device 3b may include a cell area CELL, a peripheral connection area PA, and a cell connection area EXT between the cell area CELL and the peripheral connection area PA. The cell area CELL may be adjacent to the cell connection area EXT, and the cell connection area EXT may be adjacent to the peripheral connection areas PA.

A pad pattern PAD may extend in the first horizontal direction (X direction) from the peripheral connection area PA to the dummy cell area DCR, extending across the cell connection area EXT, so as to be located over the peripheral connection area PA, the cell connection area EXT, and the dummy cell area DCR. At least a portion of the pad pattern PAD may be exposed to the outside of the nonvolatile memory device 3b through a pad opening POP.

The common source line layer CSL may have at least one common source opening CSLO. A plurality of cell channel structures CHS may be arranged in the real cell area RCR and a plurality of dummy structures DCS may be arranged in the dummy cell area DCR and the cell connection area EXT. The dummy structure DCS arranged in the dummy cell area DCR may be referred to as a cell dummy structure, and the dummy structure DCS arranged in the cell connection area EXT may be referred to as a connection dummy structure. A plurality of cell channel structures CHS may extend through the stacked mold SMLD in the vertical direction (the Z direction) so as to be connected to the common source line layer CSL. Some of the dummy structures DCS arranged in the dummy cell area DCR and the cell connection area EXT may extend through the stacked mold SMLD in the vertical direction (the Z direction) so as to be connected to the common source line layer CSL, and others thereof may extend in the vertical direction (Z direction) through the stacked mold SMLD and into the at least one common source opening CSLO. At least some of the dummy structures DCS may overlap the pad pattern PAD in the vertical direction (the Z direction). The dummy structures DCS penetrating through the stacked mold SMLD and extending into the at least one common source opening CSLO may perform the function of the support structure SPS illustrated in FIG. 6A. The stacked mold SMLD may form a stepped structure in the vertical direction (Z direction) in the cell connection area EXT.

In some embodiments, the dummy structures DCS that do not perform the function of the support structure SPS among the dummy structures DCS arranged in the dummy cell area DCR may be electrically connected to the upper bonding pad BPD, but the inventive concept is not limited thereto. For example, the bit line contact BLC may not be connected to the lower surface of each of the dummy structures DCS so that all the dummy structures DCS are not electrically connected to the upper bonding pad BPD.

In some embodiments, at least a portion of the cell channel structure CHS and at least a portion of the dummy structure DCS may be formed together through the same manufacturing process. For example, the dummy structure DCS may have a structure identical to or substantially similar to the cell channel structure CHS. In some embodiments, all the dummy structures DCS or the dummy structures DCS that perform the function of the support structure SPS may have the same structure as one of the support structure SPS illustrated in FIG. 6A, the support structure SPSa illustrated in FIG. 6B, the support structure SPSb illustrated in FIG. 6C, and the support structure SPSc illustrated in FIG. 6D.

Referring to FIG. 9C, a nonvolatile memory device 3c may include a cell area CELL, a peripheral connection area PA, and a cell connection area EXT between the cell area CELL and the peripheral connection area PA. The cell area CELL may be laterally adjacent to the cell connection area EXT, and the cell connection area EXT may be laterally adjacent to the peripheral connection areas PA.

A pad pattern PAD may extend in the first horizontal direction (X direction) from the peripheral connection area PA to the real cell area RCR through the cell connection area EXT and the dummy cell area DCR so as to extend across the peripheral connection area PA, the cell connection area EXT, the dummy cell area DCR, and at least a portion of the real cell area RCR. At least a portion of the pad pattern PAD may be exposed to the outside of the nonvolatile memory device 3c through a pad opening POP.

The common source line layer CSL may have a common source opening CSLO. A plurality of cell channel structures CHS may be arranged in the real cell area RCR and a plurality of dummy structures DCS may be arranged in the dummy cell area DCR and the cell connection area EXT.

Some of the cell channel structures CHS and some of the dummy structures DCS arranged in the dummy cell area DCR and the cell connection area EXT may penetrate through the stacked mold SMLD and extend in the vertical direction (the Z direction) so as to be connected to the common source line layer CSL, and others of the cell channel structures CHS and others of the dummy structures DCS arranged in the dummy cell area DCR and the cell connection area EXT may penetrate through the stacked mold SMLD and extend into at least one common source opening CSLO. Some of the cell channel structures CHS and at least some of the dummy structures DCS may overlap the pad pattern PAD in the vertical direction (the Z direction). The cell channel structures CHS and the dummy structures DCS penetrating through the stacked mold SMLD and extending into the at least one common source opening CSLO may perform the function of the support structure SPS illustrated in FIG. 6A. The stacked mold SMLD may form a stepped structure in the vertical direction (Z direction) in the cell connection area EXT.

In some embodiments, the cell channel structures CHS and the dummy structures DCS that perform the function of the support structure SPS may not be electrically connected to the upper bonding pad BPD. For example, the bit line contact BLC may not be connected to the lower surface of each of the cell channel structures CHS and the dummy structures DCS that perform the function of the support structure SPS.

FIGS. 10A and 10B are schematic cross-sectional views of an example nonvolatile memory device according to embodiments. Specifically, FIG. 10B is an enlarged cross-sectional view of region XB of FIG. 10A.

Referring to FIG. 10A, a nonvolatile memory device 100 may include a peripheral circuit structure PS and a cell array structure CS on the peripheral circuit structure PS (e.g., bonded to each other) in the vertical direction (the Z direction). The peripheral circuit structure PS and the cell array structure CS may be referred to as a first structure and a second structure, or a lower structure and an upper structure. The peripheral circuit structure PS may include the peripheral circuit 30 described with reference to FIG. 1, and the cell array structure CS may include the memory cell array 20 described with reference to FIG. 1. The cell array structure CS may include memory cells arranged three-dimensionally. The cell array structure CS may include a cell area CELL, and a peripheral connection area PA laterally adjacent to the cell area CELL. The cell area CELL may include a real cell area RCR and a dummy cell area DCR. Components for electrically connecting the cell area CELL to the peripheral circuit structure PS including a component for electrically connecting a common source line layer 210 to the peripheral circuit structure PS may be arranged in the peripheral connection area PA.

The peripheral circuit structure PS may include a substrate 110 on which a peripheral circuit 120 is disposed, a lower interconnect structure 130 electrically connected to the peripheral circuit 120, a lower bonding pad 150 electrically connected to the peripheral circuit 120 through the lower interconnect structure 130, and a lower insulating structure 140 on the substrate 110 and the peripheral circuit 120.

The substrate 110 may include, for example, a semiconductor material, such as a Group IV semiconductor material, a Group III-V semiconductor material, a Group II-VI semiconductor material, or a Group II-VI oxide semiconductor material. The Group IV semiconductor material may include, for example, silicon (Si), germanium (Ge), or silicon-germanium (Si—Ge). The Group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The Group II-VI semiconductor material may include, for example, zinc telluride (ZnTe) or cadmium sulfide (CdS). The substrate 110 may be provided as a bulk wafer or an epitaxial layer. In another embodiment, the substrate 110 may include a silicon-on-insulator (SOI) substrate or a germanium-on-insulator (GeOI) substrate. An active area AC may be defined in the substrate 110 by a device isolation layer 112, and a plurality of peripheral circuits 120 may be formed on the active area AC. The peripheral circuits 120 may include a peripheral circuit gate 122 and source/drain regions 124 arranged in portions of the substrate 110 on both sides of the peripheral circuit gate 122 in the second horizontal direction (Y direction).

The lower interconnect structure 130 may include a plurality of peripheral circuit wiring layers 132 and a plurality of peripheral circuit contacts 134. The lower interconnect structure 130 may include a conductive material, such as copper (Cu), aluminum (Al), tungsten (W), silver (Ag), gold (Au), or any combination thereof. The lower bonding pad 150 may be disposed on the lower interconnect structure 130 and electrically connected to the peripheral circuit 120 and/or the substrate 110 through the lower interconnect structure 130. The lower insulating structure 140 may surround the peripheral circuit 120, the lower interconnect structure 130, and the lower bonding pad 150 on the substrate 110. The lower bonding pad 150 may have an upper surface disposed on the same plane as (i.e., coplanar with) the upper surface of the lower insulating structure 140.

In some embodiments, the lower insulating structure 140 may include an insulating material including silicon oxide, silicon nitride, a low-k material, or any combination thereof. The low-k material is a material having a lower dielectric constant than silicon oxide and may include, for example, phosphosilicate glass (PSG), borophosphosilicate glass (BPSG), fluorosilicate glass (FSG), organosilicate glass (OSG), spin-on-glass (SOG), spin-on-polymer, or any combination thereof, although embodiments are not limited thereto. In some embodiments, the lower insulating structure 140 may include an ultra-low k (ULK) layer having an ultra-low dielectric constant K of about 2.2 to about 2.4. The ULK layer may include, for example, SiOC or SiCOH. The lower bonding pad 150 may include a conductive material including copper (Cu), gold (Au), silver (Ag), aluminum (Al), tungsten (W), titanium (Ti), tantalum (Ta), or any combination thereof, although embodiments are not limited thereto.

The cell array structure CS may include a common source line layer 210, a cell stack 220 disposed under the common source line layer 210, an upper interconnect structure 240 electrically connected to the cell stack 220, an upper bonding pad 260 electrically connected to the upper interconnect structure 240, and an upper insulating structure 250 covering the cell stack 220 below the cell stack 220 and surrounding the bit line contact BLC, the bit line BL, the upper interconnect structure 240, and the upper bonding pad 260. The upper bonding pad 260 may have a lower surface disposed on the same plane as the lower surface of the upper insulating structure 250.

The nonvolatile memory device 100 may further include a base insulating layer 202 covering the common source line layer 210 on the cell stack 220, a pad pattern 330 disposed on the base insulating layer 202, and a protective insulating layer 350 covering a portion of the pad pattern 330 on the base insulating layer 202. The protective insulating layer 350 may have a pad opening 3500 that exposes the upper surface of the remaining portion of the pad pattern 330 without covering the upper surface of the remaining portion of the pad pattern 330. The base insulating layer 202 may include the same insulating material. The pad pattern 330 may extend from the peripheral connection area PA to the dummy cell area DCR so as to be located across the peripheral connection area PA and the dummy cell area DCR.

The common source line layer 210 may be the common source line layer CSL illustrated in FIGS. 5A to 7B and 9A to 9C. The cell stack 220, the upper interconnect structure 240, and the upper bonding pad 260 may be the stacked mold SMLD, the upper interconnect structure ITCS, and the upper bonding pad BPD, respectively, illustrated in FIGS. 6A to 7B and FIGS. 9A to 9C.

Although FIG. 10A illustrates that the upper interconnect structure 240 includes only a plurality of contacts, this is only an example and the inventive concept is not limited thereto. For example, similar to the lower interconnect structure 130 including the peripheral circuit wiring layers 132 and the peripheral circuit contacts 134, the upper interconnect structure 240 may include a plurality of wiring layers and a plurality of contacts. The upper interconnect structure 240 and the upper insulating structure 250 may include the same or similar materials as the lower interconnect structure 130 and the lower insulating structure 140, respectively.

The upper insulating structure 250 may be in contact with the lower insulating structure 140, and the upper bonding pad 260 may be in contact with the corresponding lower bonding pad 150, and then, the bonding may be performed so that the cell array structure CS is bonded to the peripheral circuit structure PS. For example, the peripheral circuit structure PS and the cell array structure CS may be bonded to each other by a metal-oxide hybrid bonding method. Accordingly, the upper interconnect structure 240 included in the cell array structure CS may be electrically connected to the peripheral circuit 120 included in the peripheral circuit structure PS.

The cell stack 220 may include a plurality of gate electrodes 222 and a plurality of insulating layers 224, which are alternately stacked in the vertical direction (Z direction) under the common source line layer 210. The gate electrodes 222 may include tungsten (W), copper (Cu), silver (Ag), gold (Au), aluminum (Al), or any combination thereof, but may include a conductive material not limited thereto. The insulating layers 224 may each include an insulating material that may include silicon oxide, a low-k material, or any combination thereof, although embodiments are not limited thereto.

A buffer insulating layer 212 may be between the common source line layer 210 and the cell stack 220. For example, the buffer insulating layer 212 may be between the common source line layer 210 and the gate electrode 222 at the top of the cell stack 220. The buffer insulating layer 212 may include an insulating material such as oxide. The buffer insulating layer 212 may have a thickness in the vertical direction (Z direction) of tens to hundreds of nanometers (nm). The thickness of the gate electrode 222 in the vertical direction may be greater than or equal to the thickness of the insulating layer 224. For example, the gate electrode 222 may have a thickness of about 10 nm to about 20 nm and the insulating layer 224 may have a thickness of about 10 nm to about 15 nm.

A plurality of cell channel structures 230 extending vertically through the cell stack 220 including the gate electrodes 222 and the insulating layers 224 may be disposed in the real cell area RCR. A memory cell string (see MS of FIG. 3) including a plurality of memory cells may be provided along each of the cell channel structures 230. Each of the cell channel structures 230 may extend through the cell stack 220 and the buffer insulating layer 212 into the common source line layer 210 in the vertical direction (the Z direction). For example, a portion of the upper side of each of the cell channel structures 230 may protrude (i.e., extend) from the upper surface of the buffer insulating layer 212 in the vertical direction (the Z direction) and may be arranged within the common source line layer 210. The cell channel structure 230 may be the cell channel structure CHS illustrated in FIGS. 6A to 7B and 9A to 9C.

In some embodiments, the nonvolatile memory device 100 may further include a word line cut area WLC extending vertically in the cell stack 220. The word line cut area WLC may penetrate through the cell stack 220 and extend vertically into the common source line layer 210. The word line cut area WLC may be apart from the cell channel structures 230. In some embodiments, the word line cut area WLC may extend in the first horizontal direction (the X direction) along between the cell channel structures 230 adjacent to each other in the second horizontal direction (the Y direction). The word line cut area WLC may include an oxide layer, a nitride layer, or any combination thereof.

The common source line layer 210 may function as a source region configured to supply a current to the memory cells formed in the cell array structure CS. The common source line layer 210 may correspond to the common source line CSL illustrated in FIG. 3. The common source line layer 210 may include a semiconductor material, such as a Group IV semiconductor material, a Group III-V semiconductor material, or a Group II-VI semiconductor material. For example, the common source line layer 210 may include at least one of silicon (Si), germanium (Ge), silicon germanium (SiGe), gallium arsenide (GaAs), indium gallium arsenide (InGaAs), aluminum gallium arsenide (AlGaAs), or any mixture thereof, although embodiments are not limited thereto. Also, the common source line layer 210 may include a semiconductor doped with n-type impurities. In addition, the common source line layer 210 may have a crystal structure including at least one structure type selected from single crystal, amorphous, and polycrystalline structures. In some embodiments, the common source line layer 210 may include a carbon-free semiconductor material. For example, the common source line layer 210 may include polysilicon. In some embodiments, the common source line layer 210 may include carbon-free polysilicon. In some examples, the common source line layer 210 may include polysilicon doped with n-type impurities.

The common source line layer 210 may be disposed so that the cell channel structure 230 penetrates through the gate electrodes 222 and the insulating layers 224 and comes into contact with the common source line layer 210. The common source line layer 210 may extend along the lower surface of the base insulating layer 202 and may surround a portion of the upper side of each of the cell channel structures 230.

In some embodiments, the gate electrodes 222 may correspond to the at least one ground select line GSL, the word lines WL (WL1, WL2, . . . , WLn−1, WLn), and the at least one string select line SSL, which constitute the memory cell string MS illustrated in FIG. 3. For example, the gate electrode 222 arranged closest to the common source line layer 210 in the vertical direction (e.g., the uppermost gate electrode 222) may function as the ground select line GSL, at least two gate electrodes 222 arranged farthest from the common source line layer 210 in the vertical direction (e.g., the two lowermost gate electrodes 222) may function as the string select lines SSL, and the remaining gate electrodes 222 may function as the word lines WL. Accordingly, a memory cell string MS in which the ground select transistor GST, the string select transistor SST, and the memory cell transistors MC1, MC2, . . . , MCn−1, and MCn therebetween, which are illustrated in FIG. 3, are connected in series may be provided.

In some embodiments, at least one of the gate electrodes 222 may function as the dummy word line. For example, at least one gate electrode 222 functioning as an additional dummy word line may be between the gate electrode 222 functioning as the ground select line GSL and the common source line layer 210, at least one gate electrode 222 functioning as an additional dummy word line may be between the gate electrode 222 functioning as the ground select line GSL and the gate electrode 222 functioning as the word line WL, and at least one gate electrode 222 functioning as an additional dummy word line may be between the gate electrode 222 functioning as the word line WL and the gate electrode 222 functioning as the string select line SSL.

The cell channel structures 230 may be spaced apart from each other at certain intervals in the first horizontal direction (the X direction), the second horizontal direction (the Y direction), and the third horizontal direction (e.g., a diagonal direction with respect to the first horizontal direction (the X direction) and the second horizontal direction (the Y direction)). The cell channel structures 230 may be arranged in a zigzag shape or a staggered shape. The cell channel structures 230 may each include a conductive plug 238. The conductive plug 238 may be arranged at one end of each of the cell channel structures 230 opposite to the common source line layer 210.

The cell channel structures 230 may be arranged within a plurality of channel holes CHH in the real cell area RCR. The channel holes CHH may extend vertically (i.e., in the Z direction) through the buffer insulating layer 212 and the cell stack 220 including the gate electrodes 222 and the insulating layers 224 and extend partially into the common source line layer 210. The channel holes CHH may be defined by the gate electrodes 222 and the insulating layers 224 within the cell stack 220 and may be defined by the common source line layer 210.

Each of the cell channel structures 230 may include a gate insulating layer 232, a channel layer 234, a buried insulating layer 236, and the conductive plug 238, as shown in FIGS. 10A and 10B. The gate insulating layer 232 and the channel layer 234 may be sequentially disposed on the inner wall of the channel hole CHH. For example, the gate insulating layer 232 may conformally cover the cell stack 220 including the insulating layers 224 and the inner wall (sidewall) of the channel hole CHH penetrating through the buffer insulating layer 212, and the channel layer 234 may conformally cover the inner wall and ceiling (i.e., upper) surface of the channel hole CHH. The channel layer 234 may cover the inner wall and ceiling surface of the channel hole CHH extending into the common source line layer 210 so as to come into contact with the common source line layer 210. The gate insulating layer 232 may not extend into the common source line layer 210. For example, the top surface of the gate insulating layer 232 may be in contact with the lower surface of the common source line layer 210, such that the top surface of the gate insulating layer 232 may be coplanar with the lower surface of the common source line 210 with respect to an upper surface of the substrate 110 as a reference layer. The channel layer 234 may extend into the common source line layer 210 along the inner wall of the channel hole CHH extending into the common source line layer 210. For example, the top of the channel layer 234 may be located at a vertical level higher than the lower surface of the common source line layer 210 relative to the upper surface of the substrate 110. The lower surface of the common source line layer 210 refers to the lowermost surface of the common source line layer 210 excluding the inner wall and ceiling surface of the channel hole CHH extending into the common source line layer 210.

The buried insulating layer 236 filling the remaining space of the channel hole CHH may be disposed on the channel layer 234. The conductive plug 238 that is in contact with the channel layer 234 and blocks the entrance of the channel hole CHH may be disposed on the lower side of the channel hole CHH. In some embodiments, the buried insulating layer 236 may be omitted and the channel layer 234 may be formed in a pillar shape to fill the remaining portion of the channel hole CHH.

The gate electrode 222 may include metal, such as tungsten, nickel, cobalt, and tantalum, a conductive metal nitride, such as titanium nitride, tantalum nitride, and tungsten nitride, a metal silicide, such as tungsten silicide, nickel silicide, cobalt silicide, and tantalum silicide, doped polysilicon, or any combination thereof, although embodiments are not limited thereto. In some embodiments, a dielectric liner may be between the gate electrode 222 and the insulating layer 224. The dielectric liner may include a high-dielectric constant (high-k) material such as aluminum oxide.

The gate insulating layer 232 may have a structure including a tunneling dielectric layer 232A, a charge storage layer 232B, and a blocking dielectric layer 232C, which are sequentially disposed on the outer wall of the channel layer 234 in this stated order. The relative thicknesses of the tunneling dielectric layer 232A, the charge storage layer 232B, and the blocking dielectric layer 232C constituting the gate insulating layer 232 are not limited to the thickness illustrated in FIG. 10B and may be variously modified.

The tunneling dielectric layer 232A may include silicon oxide, hafnium oxide, aluminum oxide, zirconium oxide, tantalum oxide, and the like, although embodiments are not limited thereto. The charge storage layer 232B is a region where electrons passing from the channel layer 234 through the tunneling dielectric film 232A may be stored, and may include silicon nitride, boron nitride, silicon boron nitride, or polysilicon doped with impurities. The blocking dielectric layer 232C may include, for example, silicon oxide, silicon nitride, or a metal oxide with a higher dielectric constant than silicon oxide. The metal oxide may include hafnium oxide, aluminum oxide, zirconium oxide, tantalum oxide, or any combination thereof, although embodiments are not limited thereto.

The bit lines BL may extend apart from each other in the first horizontal direction (the X direction), but the inventive concept is not limited thereto. For example, the bit lines BL may extend apart from each other in the second horizontal direction (the Y direction). The bit line BL may be electrically connected to the cell channel structure 230 by the bit line contact BLC. The bit line contact BLC may be connected to the conductive plug 238.

A plurality of dummy structures 230D may be arranged within the channel holes CHH in the dummy cell area DCR. The dummy structure 230D may be formed to prevent leaning or bending of the gate electrode 222 and ensure structural stability during the process of manufacturing the nonvolatile memory device 100. In some embodiments, the dummy structure 230D may have substantially the same or similar structure and shape as the cell channel structure 230. When the dummy structure 230D has the same or similar structure and shape as the cell channel structure 230, the cell channel structure 230 may be referred to as a real cell channel structure and the dummy structure 230D may be referred to as a dummy cell channel structure. For example, the dummy structure 230D may include the gate insulating layer 232, the channel layer 234, and the buried insulating layer 236, but may not include the conductive plug 238. In other embodiments, the cell channel structure 230 and the dummy structure 230D may have different structures and shapes. The dummy structure 230D may be the dummy structure DCS illustrated in FIGS. 6A to 7B and 9A to 9C.

A filling insulating layer 228 that fills portions corresponding to the cell stack 220 may be arranged in the peripheral connection area PA. The upper insulating structure 250 may cover the cell stack 220 and the filling insulating layer 228. In some embodiments, the upper insulating structure 250 may include a plurality of insulating layers. Each of the insulating layers may be disposed to cover the bit line contact BLC, the bit line BL, and the upper interconnect structure 240. A through-contact plug IOMC that penetrates through the filling insulating layer 228 and is electrically connected to the peripheral circuit 120 through the upper interconnect structure 240 and the lower interconnect structure 130 may be arranged in the peripheral connection area PA. The through-contact plug IOMC may extend into the base insulating layer 202.

In some embodiments, the cell channel structures 230, the dummy structures 230D, and the through-contact plug IOMC may each have a tapered shape in which the horizontal width thereof increases while extending downward in the vertical direction (the Z direction) from the common source line layer 210 and the base insulating layer 202 toward the peripheral circuit structure PS.

The common source line layer 210 may have a common source opening 2100. The common source opening 2100 may be the common source opening CSLO illustrated in FIGS. 5A to 7B and 9A to 9C. In some embodiments, the common source opening 2100 may not be located in the peripheral connection area PA and may be located only in the cell area CELL. The pad pattern 330 may extend in the second horizontal direction (Y direction) from the peripheral connection area PA onto the common source opening 2100. In some embodiments, the common source opening 2100 may be located in the dummy cell area DCR and may not be located in the real cell area RCR. The base insulating layer 202 may at least partially fill the common source opening 2100.

Some of the dummy structures 230D may penetrate through the cell stack 220 and extend in the vertical direction (the Z direction) so as to be connected to the common source line layer 210, and others of the dummy structures 230D may penetrate through the cell stack 220 and extend into the base insulating layer 202 filling the common source opening 2100. At least some of the dummy structures 230D may overlap the pad pattern 330 in the vertical direction (the Z direction). Others of the dummy structures 230D penetrating through the cell stack 220 and extending into the common source opening 2100 may perform the function of the support structure SPS.

A pad connection via 325 may be between the pad pattern 330 and the through-contact plug IOMC in the vertical direction (Z direction). The upper and lower surfaces of the pad connection via 325 may be in contact with the lower surface of the pad pattern 330 and the upper surface of the through-contact plug IOMC, respectively. A pad support via 328 may be between the pad pattern PAD and the dummy structure 230D that performs the function of the support structure SPS in the vertical direction. The upper and lower surfaces of the pad support via 328 may be in contact with the lower surface of the pad pattern 330 and the upper surface of the dummy structure 230D that performs the function of the support structure SPS, respectively. The pad connection via 325 and the pad support via 328 may penetrate through the base insulating layer 202. The pad connection via 325 and the pad support via 328 may be the pad connection via PCOT and the pad support via SCOT illustrated in FIGS. 6A to 7B and 9A to 9C.

The cell channel structures 230 and the through-contact plug IOMC may be electrically connected to the upper bonding pad 260. The cell channel structures 230 and the through-contact plug IOMC may be electrically connected to the peripheral circuit 120 included in the peripheral circuit structure PS through the upper bonding pad 260. The cell channel structures 230 and the through-contact plug IOMC may be electrically connected to the bit line BL. The cell channel structures 230 and the through-contact plug IOMC may be electrically connected to the bit line BL through the bit line contact BLC. The bit line BL may be electrically connected to the upper bonding pad 260 through the upper interconnect structure 240. For example, the bit line contact BLC, the bit line BL, and the upper interconnect structure 240 may be sequentially arranged between each of the cell channel structures 230 and the at through-contact plug IOMC and the upper bonding pad 260.

The dummy structure 230D that performs the function of the support structure SPS may not be electrically connected to the upper bonding pad BPD. The dummy structure 230D that performs the function of the support structure SPS may not be electrically connected to the bit line BL. For example, the bit line contact BLC may be connected to the lower surface of each of the cell channel structures 230 and the through-contact plug IOMC, but the bit line contact BLC may not be connected to the lower surface of the dummy structure 230D that performs the function of the support structure SPS. In some embodiments, the upper insulating structure 250 may cover the lower surface of the dummy structure 230D that performs the function of the support structure SPS.

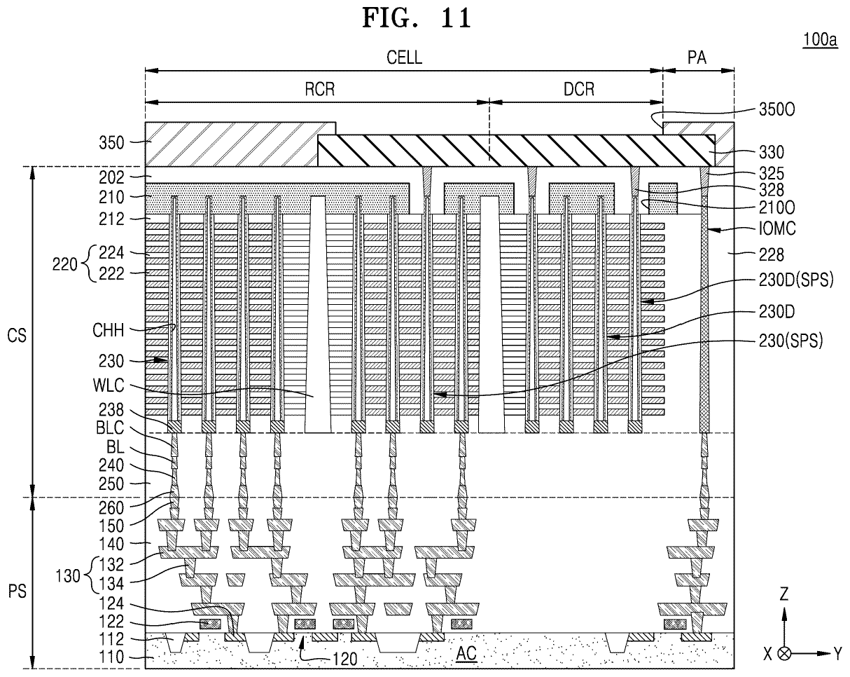

FIG. 11 is a cross-sectional view of a nonvolatile memory device according to embodiments.

Referring to FIG. 11, a nonvolatile memory device 100a may include a peripheral circuit structure PS and a cell array structure CS on the peripheral circuit structure PS (e.g., bonded to each other) in the vertical direction (the Z direction). The cell array structure CS may include a cell area CELL and a peripheral connection area PA laterally adjacent to the cell area CELL. The cell area CELL may include a real cell area RCR and a dummy cell area DCR laterally adjacent to the real cell area RCR.

A pad pattern 330 may extend in the second horizontal direction (Y direction) from the peripheral connection area PA to the real cell area RCR through the dummy cell area DCR so as to extend across (i.e., over) the peripheral connection area PA, the dummy cell area DCR, and the real cell area RCR.

The common source line layer 210 may have one or more common source openings 2100. The common source opening 2100 may be not located in the peripheral connection area PA and may be located only in the cell area CELL. In some embodiments, the common source opening 2100 may be located in the real cell area RCR and the dummy cell area DCR. A base insulating layer 202 may at least partially fill the common source opening 2100.

Some of the cell channel structures 230 may penetrate through the cell stack 220 and extend in the vertical direction (the Z direction) so as to be connected to the common source line layer 210, and others of the cell channel structures 230 may penetrate through the cell stack 220 and extend into the base insulating layer 202 filling the common source opening 2100. Some of the dummy structures 230D may penetrate through the cell stack 220 and extend in the vertical direction (the Z direction) so as to be connected to the common source line layer 210, and others of the dummy structures 230D may penetrate through the cell stack 220 and extend into the common source opening 2100.

Some of the cell channel structures 230 and at least some of the dummy structures 230D may overlap the pad pattern 330 in the vertical direction (the Z direction). Others of the cell channel structures 230 and others of the dummy structures 230D, which each vertically extend through the cell stack 220 and extend into the common source opening 2100, may be connected to the pad support via 328 and perform the function of the support structure SPS. The cell channel structure 230 and the dummy structure 230D that perform the function of the support structure SPS may not be electrically connected to the upper bonding pad BPD. The bit line contact BLC may not be connected to the lower surface of the cell channel structure 230 and the lower surface of the dummy structure 230D, which perform the function of the support structure SPS. In some embodiments, the upper insulating structure 250 may cover the lower surface of the cell channel structure 230 and the lower surface of the dummy structure 230D, which perform the function of the support structure SPS.

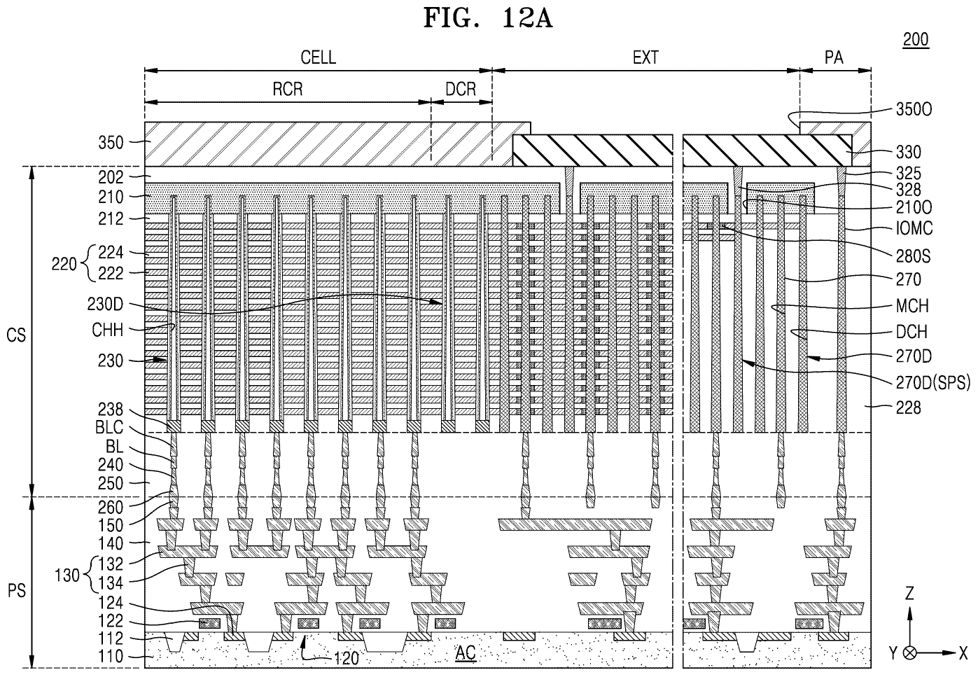

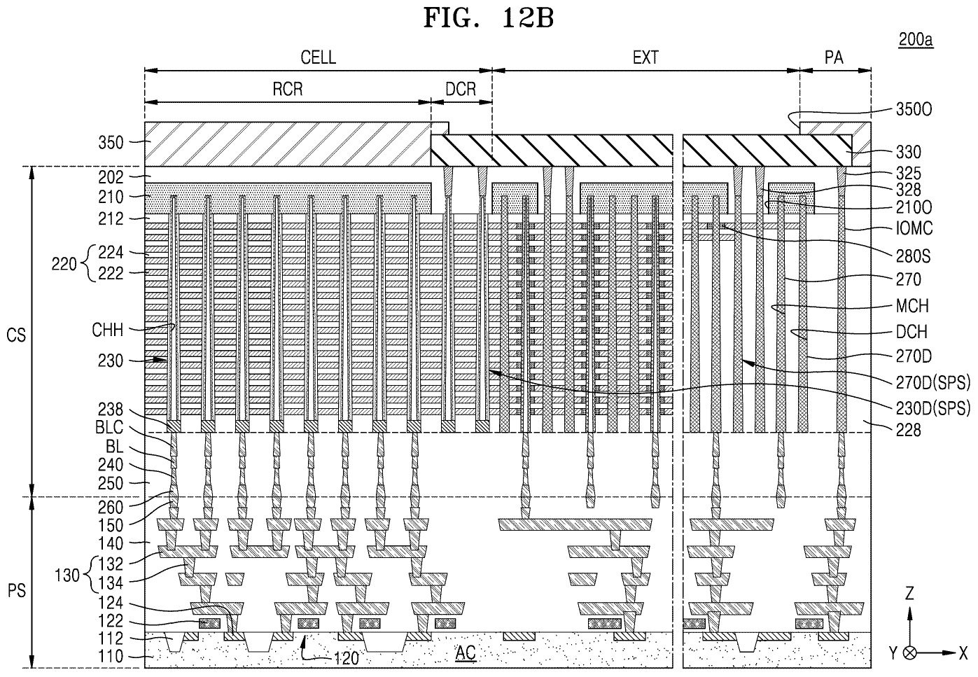

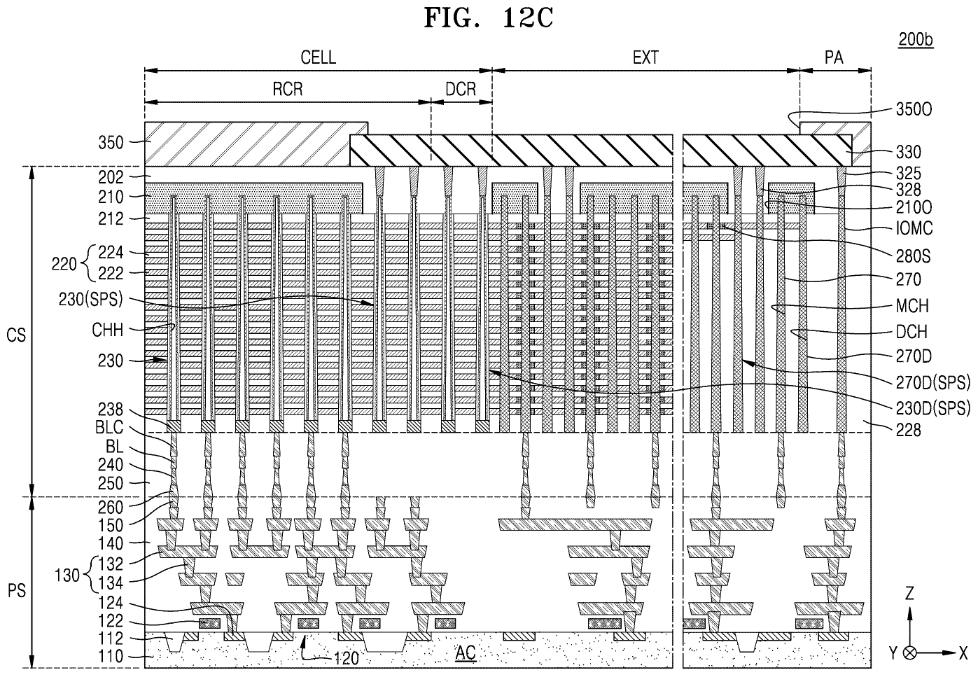

FIGS. 12A to 12C are schematic cross-sectional views of example nonvolatile memory devices according to embodiments.

Referring to FIG. 12A, a nonvolatile memory device 200 may include a peripheral circuit structure PS and a cell array structure CS on the peripheral circuit structure PS (e.g., bonded to each other) in the vertical direction (the Z direction). The cell array structure CS may include a cell area CELL, a cell connection area EXT laterally adjacent to the cell area CELL, and a peripheral connection area PA laterally adjacent to the cell connection area EXT. The cell area CELL may include a real cell area RCR and a dummy cell area DCR. The dummy cell area DCR may be between the real cell area RCR and the cell connection area EXT.

A pad pattern 330 may extend in the first horizontal direction (X direction) from the peripheral connection area PA to the cell connection area EXT so as to extend laterally across the peripheral connection area PA and the cell connection area EXT. At least a portion of the pad pattern 330 may be exposed to the outside of the nonvolatile memory device 200 through a pad opening 3500 in a protective insulating layer 350 provided on an upper surface of the memory device 200. A cell stack 220 and a common source line layer 210 disposed on the cell stack 220 may be arranged in the cell area CELL and in at least a portion of the cell connection area EXT. The cell stack 220 and the common source line layer 210 may be arranged in the cell area CELL and the cell connection area EXT, but may not be arranged in the peripheral connection area PA.

The cell stack 220 may form a stepped structure in the vertical direction in the cell connection area EXT. A plurality of gate electrodes 222 may be stacked on the cell area CELL to be apart from each other in the vertical direction (the Z direction) and may extend from the cell area CELL to the cell connection area EXT at different lengths in the first horizontal direction (X direction) to form the stepped structure. The gate electrodes 222 may be arranged in the first horizontal direction (the X direction) to have a stepped structure between the gate electrodes 222 adjacent in the vertical direction (the Z direction), but the inventive concept is not limited thereto. For example, the gate electrodes 222 may be arranged to have a stepped structure in the second horizontal direction (the Y direction), or may be arranged to have a stepped structure in each of the first horizontal direction (the X direction) and the second horizontal direction (the Y direction).

Due to the stepped structure, each of the gate electrodes 222 may have portions extending longer in the first horizontal direction (X direction) than other gate electrodes 222 adjacent in the vertical direction (the Z direction), and each of the portions may be referred to as a gate pad portion. In some embodiments, in each of the gate electrodes 222, the gate pad portion may include an end portion in the first horizontal direction (the X direction).

The common source line layer CSL may have at least one common source opening CSLO. A plurality of cell channel structures 230 may be arranged in the real cell area RCR and a plurality of dummy structures may be arranged in the dummy cell area DCR and the cell connection area EXT. In order to distinguish between the dummy structure arranged in the dummy cell area DCR and the dummy structure arranged in the cell connection area EXT, the dummy structure arranged in the dummy cell area DCR may be referred to as a cell dummy structure 230D and the dummy structure arranged in the cell connection area EXT may be referred to as a connection dummy structure 270D.

The connection dummy structures 270D may be arranged within a plurality of dummy channel holes DCH that penetrate through the gate electrodes 222, a plurality of insulating layers 224 disposed between adjacent gate electrodes 222, and a buffer insulating layer 212 and extends in the vertical direction (the Z direction). The connection dummy structures 270D may be arranged around a plurality of gate contact plugs 270. Each of the gate contact plugs 270 may extend through the gate electrodes 222 in the vertical direction (the Z direction) in the cell connection area EXT, and may be electrically connected to the gate pad portion of a corresponding one of the gate electrodes 222. An insulating spacer 280S may be between the gate electrode 222 and the gate contact plug 270 that are not electrically connected among the gate electrodes 222 and the gate contact plugs 270. Each of the gate contact plugs 270 may be electrically connected to the upper bonding pad 260.

A filling insulating layer 228 that covers portions of the gate electrodes 222 constituting the gate pad portion and surrounds the gate contact plugs 270 may be arranged in the cell connection area EXT. The filling insulating layer 228 may also be arranged in the peripheral connection area PA. The upper insulating structure 250 may cover the cell stack 220 and the filling insulating layer 228.

Some of the connection dummy structures 270D arranged in the cell connection area EXT may penetrate through the cell stack 220 and extend in the vertical direction (the Z direction) so as to be connected to the common source line layer 210, and others thereof may penetrate through the cell stack 220 and extend into at least one common source opening 2100. At least some of the connection dummy structures 270D may overlap the pad pattern 330 in the vertical direction (the Z direction). The connection dummy structures 270D that penetrate through the cell stack 220 and extend into the at least one common source opening 2100 may be connected to the pad support via 328 and perform the function of the support structure SPS illustrated in FIG. 9A. The connection dummy structures 270D that perform the function of the support structure SPS may not be electrically connected to the upper bonding pad BPD. In some embodiments, the upper insulating structure 250 may cover the lower surface of each of the connection dummy structures 270D that perform the function of the support structure SPS.

Although FIG. 12A illustrates that the cell channel structure 230 and the cell dummy structure 230D have the same or substantially similar structure and the gate contact plug 270 and the connection dummy structure 270D have the same or substantially similar structure, this is only an example and the inventive concept is not limited thereto. For example, each of the cell dummy structure 230D and the connection dummy structure 270D may have the same structure as one of the support structure SPS illustrated in FIG. 6A, the support structure SPSa illustrated in FIG. 6B, the support structure SPSb illustrated in FIG. 6C, and the support structure SPSc illustrated in FIG. 6D.

Referring to FIG. 12B, a nonvolatile memory device 200a may include a cell area CELL, a peripheral connection area PA, and a cell connection area EXT between the cell area CELL and the peripheral connection area PA in the first horizontal direction (X direction). A pad pattern 330 may extend from the peripheral connection area PA to a dummy cell area DCR through the cell connection area EXT so as to be located across the peripheral connection area PA, the cell connection area EXT, and the dummy cell area DCR.

The common source line layer CSL may have a common source opening CSLO. A plurality of cell channel structures CHS may be arranged in a real cell area RCR, a plurality of cell dummy structures 230D may be arranged in the dummy cell area DCR, and a plurality of connection dummy structures 270D may be arranged in the cell connection area EXT.

Some of the cell dummy structures 230D and some of the connection dummy structures 270D may penetrate through the cell stack 220 and extend in the vertical direction (the Z direction) so as to be connected to a common source line layer 210, and others of the cell dummy structures 230D and others of the connection dummy structures 270D may penetrate through the cell stack 220 and extend into at least one common source opening 2100. At least some of the cell dummy structures 230D and at least some of the connection dummy structures 270D may overlap the pad pattern 330 in the vertical direction (the Z direction). Others of the cell dummy structures 230D and others of the connection dummy structures 270D, which each penetrate through the cell stack 220 and extend into the common source opening 2100, may be connected to the pad support via 328 and perform the function of the support structure SPS illustrated in FIG. 9B. Others of the cell dummy structures 230D and others of the connection dummy structures 270D that perform the function of the support structure SPS may not be electrically connected to the upper bonding pad 260. In some embodiments, the upper insulating structure 250 may cover the lower surfaces of others of the cell dummy structures 230D and others of the connection dummy structures 270D that perform the function of the support structure SPS.

Referring to FIG. 12C, a nonvolatile memory device 200b may include a cell area CELL, a peripheral connection area PA, and a cell connection area EXT between the cell area CELL and the peripheral connection area PA in the first horizontal direction (X direction). A pad pattern 330 may extend from the peripheral connection area PA to a real cell area RCR through the cell connection area EXT and a dummy cell area DCR so as to be located across the peripheral connection area PA, the cell connection area EXT, the dummy cell area DCR, and the real cell area RCR. At least a portion of the pad pattern 330 may be exposed to the outside of the nonvolatile memory device 200b through a pad opening 3500.

A common source line layer 210 may have a common source opening 2100. A plurality of cell channel structures 230 may be arranged in the real cell area RCR, a plurality of cell dummy structures 230D may be arranged in the dummy cell area DCR, and a plurality of connection dummy structures 270D may be arranged in the cell connection area EXT.

Some of the cell channel structures 230, some of the cell dummy structures 230D, and some of the connection dummy structures 270D may extend through the cell stack 220 and extend in the vertical direction (the Z direction) so as to be connected to the common source line layer 210, and others of the cell channel structures 230, others of the cell dummy structures 230D, and others of the connection dummy structures 270D may penetrate through the cell stack 220 and extend into at least the common source opening 2100. At least some of the cell channel structures 230, at least some of the cell dummy structures 230D, and at least some of the connection dummy structures 270D may overlap the pad pattern 330 in the vertical direction (the Z direction). Others of the cell channel structures 230, others of the cell dummy structures 230D, and others of the connection dummy structures 270D, which each penetrate through the cell stack 220 and extend into the common source opening 2100, may be connected to a pad support via 328 and perform the function of the support structure SPS illustrated in FIG. 9C. Others of the cell channel structures 230, others of the cell dummy structures 230D, and others of the connection dummy structures 270D that perform the function of the support structure SPS may not be electrically connected to the upper bonding pad 260. In some embodiments, an upper insulating structure 250 may cover the lower surfaces of others of the cell channel structures 230, others of the cell dummy structures 230D, and others of the connection dummy structures 270D that perform the function of the support structure SPS.

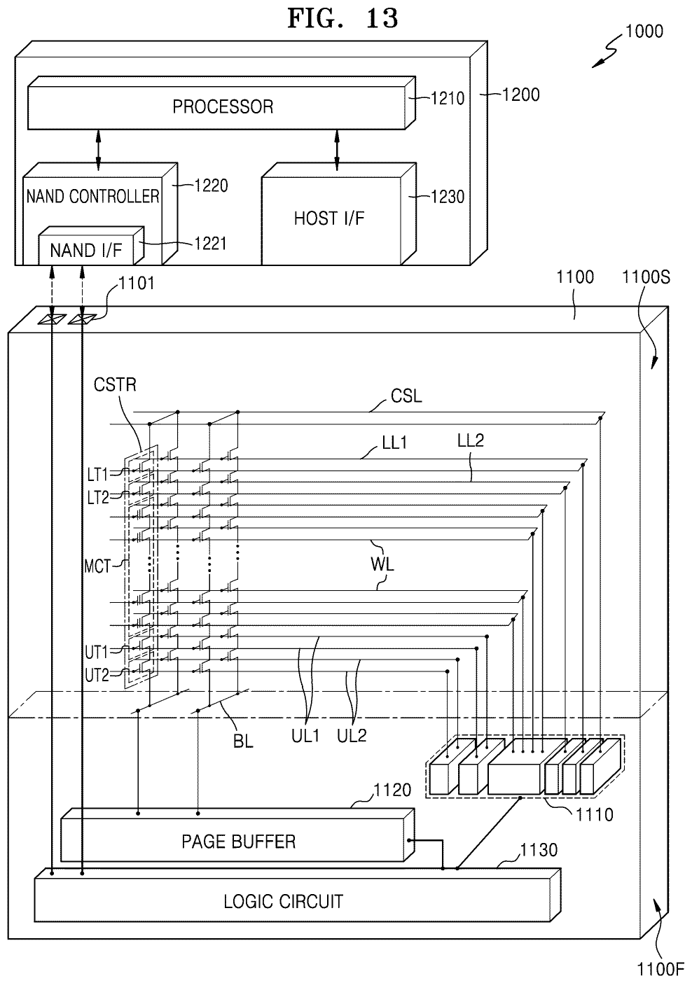

FIG. 13 is a diagram schematically illustrating a memory system including a nonvolatile memory device, according to one or more embodiments.

Referring to FIG. 13, a memory system 1000 may include at least one memory device 1100 and a memory controller 1200 electrically connected to the at least one memory device 1100. The memory system 1000 may be, for example, a solid state drive (SSD) device, a universal serial bus (USB) device, a computing system, a medical device, or a communication device, which includes the at least one memory device 1100, although embodiments are not limited thereto.

The memory device 1100 may be a nonvolatile memory device. For example, the memory device 1100 may be a NAND flash memory device including any one of the nonvolatile memory devices 1, 1-1, 1-2, 1-3, 1a, 1b, 1c, 1d, 2a, 2b, 3, 3a, 3b, 3c, 100, 100a, 200, 200a, 200b described with reference to FIGS. 4 to 12C, or any combination thereof. The at least one memory device 1100 may include a first structure 1100F and a second structure 1100S on the first structure 1100F. The first structure 1100F may correspond to the peripheral circuit structures PS illustrated in FIGS. 10A, 11, 12A, 12B, and 12C. The peripheral circuits 120 illustrated in FIGS. 10A, 11, 12A, 12B, and 12C may include a row decoder 1110, a page buffer 1120, and a logic circuit 1130.

The second structure 1100S may correspond to any of the nonvolatile memory devices 1a, 1b, lc, 1d, 2a, and 2b illustrated in FIGS. 6A to 7B, the nonvolatile memory devices 3a, 3b, and 3c illustrated in FIGS. 9A to 9C, and the cell array structures CS illustrated in FIGS. 10A, 11, 12A, 12B, and 12C. The second structure 1100S may include one or more bit lines BL, a common source line CSL, a plurality of word lines WL, first and second string select lines UL1 and UL2, first and second ground select lines LL1 and LL2, and a plurality of memory cell strings CSTR between the bit line BL and the common source line CSL. The cell channel structures 230 and the gate electrodes 222 illustrated in FIGS. 10A, 11, 12A, 12B, and 12C may form the memory cell strings CSTR.

In the second structure 1100S, the memory cell strings CSTR may each include ground select transistors LT1 and LT2 adjacent to the common source line CSL, string select transistors UT1 and UT2 adjacent to the bit line BL, and a plurality of memory cell transistors MCT between the ground select transistors LT1 and LT2 and the string select transistors UT1 and UT2. The number of ground select transistors LT1 and LT2 and the number of string select transistors UT1 and UT2 may variously change according to embodiments. One of the cell channel structures 230 and one of the gate electrodes 222 illustrated in FIGS. 10A, 11, 12A, 12B, and 12C may form one of the transistors LT1, LT2, UT1, UT2, and MCT.

In some embodiments, the ground select lines LL1 and LL2 may be electrically connected to gate electrodes of the ground select transistors LT1 and LT2, respectively. The word line WL may be electrically connected to the gate electrode of the memory cell transistor MCT. The string select lines UL1 and UL2 may be electrically connected to gate electrodes of the string select transistors UT1 and UT2, respectively.

The common source line CSL, the ground select lines LL1 and LL2, the word lines WL, and the string select lines UL1 and UL2 may be electrically connected to the row decoder 1110. The bit lines BL may be electrically connected to the page buffer 1120.

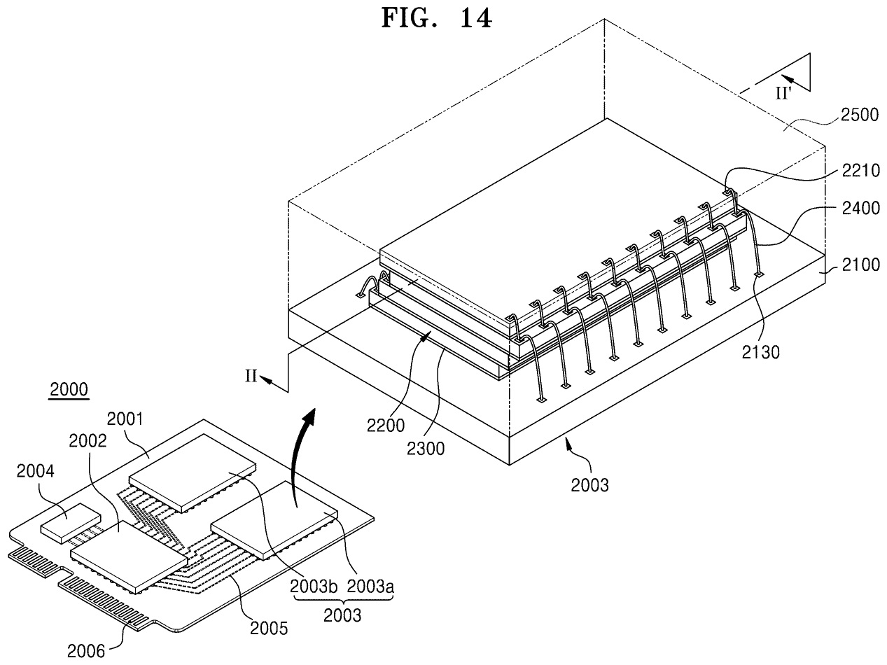

The memory device 1100 may communicate with the memory controller 1200 through at least one external connection pad 1101 electrically connected to the logic circuit 1130. The external connection pad 1101 may be electrically connected to the logic circuit 1130. The external connection pad 1101 may correspond to the pad patterns PAD illustrated in FIGS. 4A, 5A to 7B, 8A, and 9A to 9C, and the pad patterns 330 illustrated in FIGS. 10A, 11, 12A, 12B, and 12C. The memory device 1100 may be electrically connected to the memory controller 1200 through a connection structure (see 2400 of FIG. 14), such as a bonding wire connected to the external connection pad 1101.

The memory controller 1200 may include a processor 1210, a NAND controller 1220, and a host interface (I/F) 1230. In some embodiments, the memory system 1000 may include the memory devices 1100. In this case, the memory controller 1200 may control the memory devices 1100.

The processor 1210 may control overall operations of the memory system 1000 including the memory controller 1200. The processor 1210 may operate in accordance with certain firmware and may control the NAND controller 1220 to access the memory device 1100. The NAND controller 1220 may include a NAND interface 1221 that processes communication with the memory device 1100. Control commands for controlling the memory device 1100, data to be recorded on the memory cell transistors MCT of the memory device 1100, and data to be read from the memory cell transistors MCT of the memory device 1100 may be transmitted through the NAND interface 1221. The host interface 1230 may provide a communication function between the memory system 1000 and an external host. Upon receiving the control command from the external host through the host interface 1230, the processor 1210 may control the memory device 1100 in response to the control command.

FIG. 14 is a perspective view schematically illustrating a memory system including a nonvolatile memory device, according to embodiments.

Referring to FIG. 14, a memory system 2000 according to an embodiment may include a main board 2001, a memory controller 2002 provided on the main board 2001, at least one semiconductor package 2003, and a dynamic random access memory (DRAM) 2004. The at least one semiconductor package 2003 and the DRAM 2004 may be connected to the memory controller 2002 through a plurality of wiring patterns 2005 formed on the main board 2001.

The main board 2001 may include a connector 2006 including a plurality of pins to be connected to an external host. The number and arrangement of pins in the connector 2006 may vary depending on a communication interface between the memory system 2000 and the external host. In some embodiments, the memory system 2000 may communicate with the external host according to one or more interfaces, such as M-Phy for universal flash storage (UFS), universal serial bus (USB), peripheral component interconnect express (PCI-Express), and serial advanced technology attachment (SATA), although embodiments are not limited thereto. In some embodiments, the memory system 2000 may operate with power supplied from the external host through the connector 2006. The memory system 2000 may further include a power management integrated circuit (PMIC) (not explicitly shown) that distributes power supplied from the external host to the memory controller 2002 and the at least one semiconductor package 2003.

The memory controller 2002 may write data to the at least one semiconductor package 2003 or read data from the at least one semiconductor package 2003, and may improve the operating speed of the memory system 2000.

The DRAM 2004 may be a buffer memory that alleviates the speed difference between the at least one semiconductor package 2003, which is a data storage space, and the external host. The DRAM 2004 included in the memory system 2000 may operate as a type of cache memory and may provide a space for temporarily storing data during a control operation for the at least one semiconductor package 2003. When the memory system 2000 includes the DRAM 2004, the memory controller 2002 may further include a DRAM controller that controls the DRAM 2004 as well as the NAND controller that controls the at least one semiconductor package 2003.

The at least one semiconductor package 2003 may include first and second semiconductor packages 2003a and 2003b spaced apart from each other on the main board 2001. Each of the first and second semiconductor packages 2003a and 2003b may include a plurality of semiconductor chips 2200. Each of the first and second semiconductor packages 2003a and 2003b may include a package board 2100, a plurality of semiconductor chips 2200 on the package board 2100, an adhesive layer 2300 on the lower surface of each of the semiconductor chips 2200, a connection structure 2400 that electrically connects the semiconductor chips 2200 to the package board 2100, and a molding layer 2500 that covers the semiconductor chips 2200 and the connection structure 2400 on the package board 2100.

Each of the semiconductor chips 2200 may include at least one of the nonvolatile memory devices 1, 1-1, 1-2, 1-3, 1a, 1b, 1c, 1d, 2a, 2b, 3, 3a, 3b, 3c, 100, 100a, 200, 200a, and 200b described with reference to FIGS. 4 to 12C. Each of the semiconductor chips 2200 may include an input/output (I/O) pad 2210. The I/O pads 2210 may correspond to the pad patterns PAD illustrated in FIGS. 4A, 5A to 7B, 8A, and 9A to 9C, and the pad patterns 330 illustrated in FIGS. 10A, 11, 12A, 12B, and 12C. The package board 2100 may be a printed circuit board including a plurality of package upper pads 2130.

In some embodiments, the connection structure 2400 may be bonding wires that electrically connect the I/O pads 2210 to the package upper pads 2130. Accordingly, in the first and second semiconductor packages 2003a and 2003b, the semiconductor chips 2200 may be electrically connected to each other by a bonding wire method and may be electrically connected to the package upper pads 2130 of the package board 2100.

In some embodiments, the memory controller 2002 and the semiconductor chips 2200 may be included in a single package. In an embodiment, the memory controller 2002 and the semiconductor chips 2200 may be mounted on a separate interposer board that is different from the main board 2001, and the memory controller 2002 and the semiconductor chips 2200 may be connected to each other by wirings formed on the interposer board.

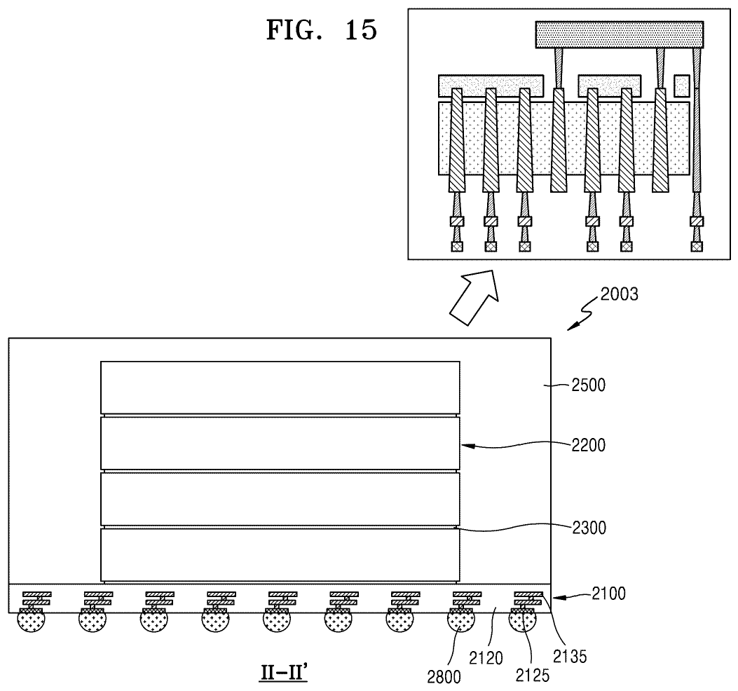

FIG. 15 is a schematic cross-sectional view schematically illustrating the example semiconductor package 2003 shown in FIG. 14, according to one or more embodiments.

Referring to FIG. 15, the package board 2100 in the semiconductor package 2003 may be a printed circuit board. The package board 2100 may include a package board body portion 2120, a plurality of package upper pads (see 2130 of FIG. 14) disposed on the upper surface of the package board body portion 2120, a plurality of lower pads 2125 disposed on or exposed through the lower surface of the package board body portion 2120, and a plurality of internal wirings 2135 that electrically connect the package upper pads (see 2130 of FIG. 14) to the lower pads 2125 within the package board body portion 2120. As illustrated in FIG. 14, the package upper pads 2130 may be electrically connected to the connection structures 2400. The lower pads 2125 may be connected to the wiring patterns 2005 on the main board 2001 of the memory system 2000 illustrated in FIG. 14 through a plurality of conductive bumps 2800. Each of the semiconductor chips 2200 may include at least one of the nonvolatile memory devices 1, 1-1, 1-2, 1-3, 1a, 1b, 1c, 1d, 2a, 2b, 3, 3a, 3b, 3c, 100, 100a, 200, 200a, and 200b described with reference to FIGS. 4 to 12C.

While the inventive concept has been particularly shown and described with reference to embodiments thereof, it will be understood that various changes in form and details may be made therein without departing from the spirit and scope of the following claims.

What is claimed is:

1. A nonvolatile memory device, comprising:
a peripheral circuit structure comprising a peripheral circuit, a lower insulating structure on the peripheral circuit, and a plurality of lower bonding pads on an upper surface of the lower insulating structure and electrically connected to the peripheral circuit;
a cell array structure having a cell area and a peripheral connection area and comprising an upper insulating structure in contact with the lower insulating structure, an upper bonding pad on a lower surface of the upper insulating structure and contacting the plurality of lower bonding pads, a cell stack in the cell area on the upper insulating structure, a common source line layer on the cell stack and having a common source opening, a plurality of cell channel structures extending in a vertical direction at least partially through the cell stack and into the common source line layer, and a support structure extending in the vertical direction at least partially through the cell stack and into the common source opening; and
a pad pattern extending in a horizontal direction, perpendicular to the vertical direction, from the peripheral connection area to the cell area on the cell array structure and overlapping the support structure in the vertical direction.

2. The nonvolatile memory device of claim 1, wherein the plurality of cell channel structures are electrically connected to some of the plurality of upper bonding pads, and the support structure is not electrically connected to the plurality of upper bonding pads.

3. The nonvolatile memory device of claim 1, wherein the cell array structure comprises a plurality of bit line contacts electrically connected to the plurality of upper bonding pads, the upper insulating structure extending around the plurality of bit line contacts,
some of the plurality of bit line contacts are respectively in contact with lower surfaces of the plurality of cell channel structures, and
the upper insulating structure is on a lower surface of the support structure.

4. The nonvolatile memory device of claim 3, wherein the cell array structure further comprises a filling insulating layer on the cell stack on the upper insulating structure, and a through-contact plug electrically connected to the pad pattern through the filling insulating layer in the peripheral connection area, and
a lower surface of the through-contact plug is in contact with one of the plurality of bit line contacts.

5. The nonvolatile memory device of claim 4, further comprising a pad connection via electrically connecting the through-contact plug to the pad pattern and a pad support via electrically connecting the support structure to the pad pattern,
wherein the pad connection via and the pad support via include a same material.

6. The nonvolatile memory device of claim 1, wherein the cell area comprises a real cell area and a dummy cell area between the real cell area and the peripheral connection area in the horizontal direction,
the support structure is in the dummy cell area, and
the pad pattern extends in the horizontal direction from the peripheral connection area to the dummy cell area.

7. The nonvolatile memory device of claim 1, wherein the cell area comprises a real cell area and a dummy cell area between the real cell area and the peripheral connection area in the horizontal direction,
a plurality of support structures are in each of the dummy cell area and the real cell area, and
the pad pattern extends in the horizontal direction from the peripheral connection area through the dummy cell area to the real cell area.

8. The nonvolatile memory device of claim 1, wherein the support structure has a same structure as each of the plurality of cell channel structures.

9. The nonvolatile memory device of claim 1, wherein the support structure includes polysilicon or a carbon-containing material.

10. The nonvolatile memory device of claim 1, wherein the support structure includes metal, conductive metal nitride, metal silicide, or any combination thereof.

11. A nonvolatile memory device, comprising:
a peripheral circuit structure comprising a peripheral circuit, a lower insulating structure on the peripheral circuit, and a plurality of lower bonding pads on an upper surface of the lower insulating structure and electrically connected to the peripheral circuit;
a cell array structure having a cell area and a peripheral connection area and comprising an upper insulating structure in contact with the lower insulating structure, an upper bonding pad on a lower surface of the upper insulating structure and contacting the plurality of lower bonding pads, a cell stack in the cell area on the upper insulating structure, a common source line layer in the cell area on the cell stack and having a common source opening, a filling insulating layer on the cell stack on the upper insulating structure, a base insulating layer at least partially filling the common source opening and on the common source line layer and the filling insulating layer, a plurality of cell channel structures extending in a vertical direction in the cell stack and extending into the common source line layer, a support structure extending in the vertical direction in the cell stack, extending into the base insulating layer, and not electrically connected to the plurality of upper bonding pads, and a through-contact plug extending in the vertical direction in the filling insulating layer in the peripheral connection area, extending into the base insulating layer, and connected to one of the plurality of upper bonding pads;
a pad pattern extending in a horizontal direction, perpendicular to the vertical direction, from the peripheral connection area to the cell area on the cell array structure, overlapping the support structure and the through-contact plug in the vertical direction, and electrically connected to the through-contact plug; and
a pad connection via and a pad support via extending in the vertical direction in the base insulating layer and connecting between the through-contact plug and the pad pattern and between the support structure and the pad pattern, the pad connection via and the pad support via including a same material.

12. The nonvolatile memory device of claim 11, wherein the common source opening is at an edge of the common source line layer in a plan view, and
a plurality of support structures extend in the vertical direction in the cell stack and the base insulating layer.

13. The nonvolatile memory device of claim 11, wherein a plurality of common source openings are spaced apart from an edge of the common source line layer and are spaced apart from each other in the horizontal direction, and
at least one of a plurality of support structures extends in the vertical direction in the cell stack and the base insulating layer.

14. The nonvolatile memory device of claim 11, wherein the cell area comprises a real cell area and a dummy cell area between the real cell area and the peripheral connection area in the horizontal direction, and
the common source opening is in the dummy cell area.

15. The nonvolatile memory device of claim 11, wherein the cell area comprises a real cell area and a dummy cell area between the real cell area and the peripheral connection area in the horizontal direction,
the common source opening is in the dummy cell area and the real cell area, and
at least one of a plurality of support structures extends in the vertical direction in the cell stack in each of the dummy cell area and the real cell area and extends into the base insulating layer.

16. The nonvolatile memory device of claim 11, wherein the cell array structure further comprises an upper interconnect structure, a bit line, and a bit line contact, which are sequentially on each of the plurality of upper bonding pads, the upper insulating structure extending around the upper interconnect structure, the bit line, and the bit line contact, and
a lower surface of each of the plurality of cell channel structures and a lower surface of the through-contact plug are in contact with the bit line contact.

17. The nonvolatile memory device of claim 16, wherein a lower surface of the support structure is not in contact with the bit line contact, and the upper insulating structure is on the lower surface of the support structure.

18. A memory system, comprising:
a nonvolatile memory device comprising: a peripheral circuit structure comprising a peripheral circuit, a lower insulating structure on the peripheral circuit, and a plurality of lower bonding pads on an upper surface of the lower insulating structure and electrically connected to the peripheral circuit; a cell array structure in contact with the peripheral circuit structure and having a cell area and a peripheral connection area; and a pad pattern extending from the peripheral connection area to the cell area on the cell array structure; and
a memory controller electrically connected to the nonvolatile memory device through a bonding wire connected to the pad pattern and configured to control the nonvolatile memory device,
wherein the cell array structure comprises
an upper insulating structure in contact with the lower insulating structure, an upper bonding pad on a lower surface of the upper insulating structure and in contact with the plurality of lower bonding pads, a cell stack in the cell area on the upper insulating structure, a common source line layer in the cell area on the cell stack and having a common source opening, a filling insulating layer on the cell stack on the upper insulating structure, a base insulating layer at least partially filling the common source opening and on the common source line layer and the filling insulating layer, a plurality of cell channel structures extending in a vertical direction through the cell stack and into the common source line layer, a support structure extending in the vertical direction through the cell stack, into the base insulating layer, and not electrically connected to the plurality of upper bonding pads, a through-contact plug extending in the vertical direction in the filling insulating layer in the peripheral connection area and into the base insulating layer, and electrically connecting the pad pattern to one of the plurality of upper bonding pads, and a pad connection via and a pad support via each extending in the vertical direction in the base insulating layer and connecting between the through-contact plug and the pad pattern and between the support structure and the pad pattern.

19. The memory system of claim 18, wherein the pad connection via and the pad support via are each in contact with a lower surface of the pad pattern and include a same material including metal.

20. The memory system of claim 18, wherein the cell array structure further comprises an upper interconnect structure, a bit line, and a bit line contact, which are sequentially on each of the plurality of upper bonding pads and surrounded by the upper insulating structure,
a lower surface of each of the plurality of cell channel structures and a lower surface of the through-contact plug are in contact with the bit line contact, and
a lower surface of the support structure is not in contact with the bit line contact, and the upper insulating structure is on the lower surface of the support structure.
